(19) United States
(12) Patent Application Publication
(10) Pub. No.: US 2006/0260938 A1
(43) Pub. Date: Nov. 23, 2006

(54) Module for Coating System and Associated Technology

(76) Inventor: Philip M. Petrach, Napa, CA (US)

Correspondence Address: PARSONS HSUE & DE RUNTZ LLP, 595 MARKET STREET, SUITE 1900, SAN FRANCISCO, CA, 94105, US

(21) Appl. No.: 11/382,240

(22) Filed: May 8, 2006

Related U.S. Application Data
(60) Provisional application No. 60/682,985, filed on May 20, 2005.

(51) Int. Cl. C23C 14/00

(52) U.S. Cl. 204/298.16; 204/298.02

(57) ABSTRACT

A module, such as a pump module or a sputtering module, comprises a lid assembly sufficient to fit or to cover a compartment, such as a pump compartment or a sputtering compartment, of a coating system, such as a modular coating system. A sputtering module comprises a power supply unit and is sufficient for receiving an electrical input and for delivering an electric output sufficient for sputtering in a sputtering compartment. A pump module, it comprises at least one pump and is sufficient for receiving an electrical input sufficient for operating the pump or pumps. Various connections between the module, external supplies, components or devices, and the compartment may be made automatically and/or manually. A control connection may be such that an external controller or a central controller is able to recognize a particular module that is associated with a particular compartment of the coating system.

### CROSS-REFERENCE TO RELATED APPLICATIONS

This application claims the benefit of U.S. Provisional Application No. 60/682,985 of Philip M. Petrach, filed on May 20, 2005, which is incorporated herein in its entirety by this reference.

### BACKGROUND

Apparatus and methods of coating substrates are of interest in connection with a variety of useful applications. By way of example, apparatus and methods employing vacuum and various process gases in the coating of large substrates, such as large sheets of glass, for example, have been of interest for some time. Large substrates, such as sheets of architectural glass, may be coated with a variety of materials to modify their optical, thermal, and/or aesthetic qualities. For example, an optical coating may be used to reduce the transmission of visible light, to decrease absorption of energy, to reduce reflectance, and/or to pursue any combination of qualities. Such an optical coating may be referred to as a solar control coating, a low emissivity coating, an anti-reflective coating, and/or a multipurpose coating, respectively. U.S. Pat. No. 6,589,657, entitled “Anti-reflection Coatings and Associated Methods,” and U.S. Published Patent Application No. 2003/0043464, entitled “Optical Coatings and Associated Methods,” each of which is incorporated herein in its entirety by this reference, describe the formation and use of coatings that affect the optical characteristics of a glass substrate.

A coating system generally includes a coater and some connected, remote units. The coater (which may also be called a coating system) generally comprises multiple process modules, or chambers, arranged in series so that a substrate or substrates can pass from one process module to the next. The substrate is generally supported and moved through the coater along a substrate passline in an upstream-to-downstream direction by rollers. The substrate generally enters the coater at one end, or upstream end, passes through multiple process modules where it is coated with a material or different materials, and exits the coater at another end, or downstream end. The substrate may be oriented so that it is horizontal or nearly so and is moved along a horizontal or nearly horizontal plane through the coater, may be oriented so that it is vertical or nearly so and is moved along a vertical or nearly vertical plane through the coater, or may be otherwise oriented and moved accordingly through the coater. Remote units connected to the coater may include electrical equipment, control electronics and other peripheral equipment. The coating of large substrates can be challenging. By way of example, architectural glass is generally produced in large sheets measuring up to 3.2 meters by 6 meters (126 inches by 236 inches), which may be difficult to handle and process in a coating system. A coating system suitable for coating large substrates, such as architectural glass, for example, may be several hundred feet long in the direction of the substrate passline, may occupy a significant amount of area in a processing facility, and may be quite expensive to purchase, house, operate and maintain.

A coater may be used in a coating process that involves the sputtering of a target material from a planar target or a cylindrical target onto the substrate as the substrate moves past the target. A system and a method for depositing material in this way via a planar target or magnetron are described in U.S. Pat. No. 4,166,018, entitled “Sputtering Process and Apparatus,” which is hereby incorporated by reference in its entirety. A system and a method for depositing material in this way via a cylindrical target or magnetron are described in U.S. Pat. No. 6,736,948, entitled “Cylindrical AC/DC Magnetron with Compliant Drive System and Improved Electrical and Thermal Isolation,” which is hereby incorporated by reference in its entirety. The sputtering of target material onto large substrates may involve the use of a high power electrical supply appropriate for sputtering and the use of cooling water for appropriate thermal control, such as the avoidance of excessive heating, for example.

Sputtering generally takes place in a vacuum environment. In this context, the term “vacuum” may refer to a gas at any pressure below atmospheric pressure. In general, sputtering processes for coating glass are carried out in the millitorr range. In sputtering processes for coating large sheets of glass, the sheets may be moved past a cylindrical target (for example) under vacuum, while the target rotates and while the target material is sputtered. The process involves maintaining a vacuum environment appropriate for sputtering, while moving parts within that vacuum environment. In some sputtering processes, a gas may be introduced into the sputtering compartment to allow reactive sputtering to take place. In general, reactive sputtering involves interaction or reaction of the gas and the sputtered target material to form a layer on a substrate. The amount of gas that may be introduced in a sputtering process is generally small so that the process pressure remains well below atmospheric pressure and the process compartment may still be considered to be under vacuum.

FIG. 1A is a schematic illustration of a coating system 100 that may be used to coat a substrate 104 or several substrates. As shown, a coater 102 of the coating system 100 may comprise a series of process modules, such as process module 106, through which a substrate, such as substrate 104, or several substrates, may pass. A process module 106 may contain multiple compartments, each of which may be configured as a sputtering compartment, a pump compartment, or a compartment sufficient for some other purpose. A substrate may be coated with a material, several layers of a material, or several materials in the process modules.

The coating system may also comprise some remote (off-coater) components, such as a power supply for sputtering, for example, as shown in FIG. 1A. A power supply unit (power supply) 112 for sputtering may be used to provide electrical power, such as a controlled electrical power, for example, to a cylindrical magnetron or a planar magnetron in the coater 102. One power supply unit is generally used for each sputtering compartment, although in some cases, two or more power supplies may be connected to one sputtering compartment. Electrical components, such as power supplies, for example, are generally located in racks that are located near or adjacent to the coater. When the coater is large, multiple racks may be used.

Merely by way of example, an electrical rack 110 may comprise power supply unit 112, as shown in FIG. 1A. A power supply unit may fit into a standard electrical rack, which has a footprint of approximately 24 inches by 24 inches. A rack may contain multiple power supply units for multiple compartments. Some power supplies are too large for such racks and may be located in dedicated cabinets. Such cabinets typically have a footprint of 60 inches by 30 inches or more. One example of a power supply used in coating systems is the Crystal power supply unit available from Advanced Energy Industries, Inc. (Fort Collins, Colo.). In order to allow access to the coater, the electrical racks or cabinets are generally located some distance away from the coater.

The coating system may also comprise cables 114 that extend from an electrical rack 110 to the coater 102, as shown in FIG. 1A. Cables 114 may lie in conduits or wire-ways. In some cases, these conduits are located in a tunnel or tunnels under a walkway area between the coater and the power supply so that the walkway is not obstructed. In other cases, large, auxiliary, above-ground racks are used to hold the conduits or the wire-ways. As shown in FIG. 1A, tunnel 116 runs between electrical rack 110 and coater 102 and carries cables 114. A typical tunnel is about 36 inches wide and about 30 inches deep. A large coater may have more than 50 sputtering compartments and may therefore have more than 50 power supplies, with as many as 6 cables for each power supply. Tunnel 116 brings cables 114 to the coater where they are then distributed along the length of the coater either in additional trenches or in overhead racks. From this point, cables extend to the individual sputtering compartments. For large coaters, cables may extend over 100 feet. A single sputtering compartment may require multiple cables or cable assemblies to connect a remote external or off-coater power supply to the compartment. For example, an existing transmission line architecture has a rating of around 70 amperes of current per cable assembly. As the power (which may be expressed in terms of current or voltage, for example) is increased, an additional cable assembly is added for each additional amount of current within a 70-ampere increment of current (for example, an additional assembly for 71-140 amperes; yet another additional assembly for 141 to 210 amperes; etc.). For example, if the power is associated with a current level of 180 amperes, three cable assemblies having about a 70-ampere rating might be used. An example of a high power or current level from an alternating current supply is greater than about 300 amperes of current, such as 400 amperes of current, merely by way of example, which may be communicated from a remote external power supply unit to the sputtering compartment via multiple cable assemblies. Each of these cable assemblies can consist of multiple conductors in an overall jacket with a diameter greater than 1 inch to handle such large currents. These multiple cable assemblies are expensive and may cost in excess of $100 per foot. The total cost of cables employed between power supplies and a coater may exceed $100,000 for large systems.

Arc suppression circuitry may be located near a magnetron of a sputtering compartment. Such arc suppression circuitry may be associated with or mounted to a lid (such as lid 130 of FIG. 1B, for example) of a sputtering compartment, for example. Other circuitry that modifies the incoming electrical supply before it goes to the magnetron may be located near the magnetron, such as in some relation to the lid. A remote power supply unit is still used to control the electrical power provided to the magnetron and is linked to the sputtering compartment via appropriate cabling. When a large amount of cabling is associated with a coater, operation of the coater may result in radio frequency (RF) noise or interference. In particular, a cable that transmits power from a remote external or off-coater power supply, to a compartment of a coater, especially in a process that employs alternating current (AC), tends to act as an antenna, radiating broadband RF noise. A cable carrying direct current (DC) may also cause interference, especially when the DC process is associated with severe arcing, for example. RF interference may affect electronic components of the coater and components of other equipment in the area. The selection, routing, shielding and grounding of such cables is generally undertaken with care to reduce or avoid such noise or interference.

FIG. 1B is a schematic illustration of a cross-section of a sputtering compartment A in process module 106 of FIG. 1A. A substrate 118 is supported and moved through sputtering compartment A by a roller 120, or typically, several such rollers (not visible in the cross-section shown) that support the substrate as it is moved, in a direction that is perpendicular to the cross-section shown, or perpendicular to the plane of the page. A target 122, such as a cylindrical target or a rotatable cylindrical target, for example, is located above substrate 118 and is supported at one end by endblock 124 and at the other end by endblock 126. The endblocks also support an array of magnets inside the target. Drive endblock 124 rotates target 122 so that sputtering erodes the target more or less evenly in a sputtering zone of the target. A motor 128 that is disposed or mounted above drive endblock 124 provides rotational force that is coupled through the drive endblock to the target. An electrical input 136 that is connected to water endblock 126 and coupled through the water endblock to the target provides electrical power for sputtering. Water endblock 126 also passes cooling water from an outside source (not shown) to the interior of the target. A description of endblocks and the use thereof is provided in the above-referenced U.S. Pat. No. 6,736,948.

Drive endblock 124 and water endblock 126 are attached to the underside of a lid 130 that fits over and seals sputtering compartment A. Lid 130 is generally a metal plate of the appropriate size to fit or to cover the top opening of sputtering compartment A. A housing or cover 132 extends over lid 130 to at least partially house or cover the components mounted to the top of lid 130, such as motor 128, for example. Lid 130 and the components attached to it form an assembly (lid assembly). The lid assembly can be raised to allow access to the interior of sputtering compartment A, as may be appropriate for maintenance or for a target change, for example. A connector 134 allows an electrical input 136 to be disconnected from the lid assembly as may be appropriate prior to moving the lid assembly, for example. A typical connector clamps an exposed metal cable to a conductive metallic block or other appropriately sized feed-through.

FIG. 2 is a schematic illustration of a cross-section of a process module 106 of FIG. 1A. In this illustration, the process module 106 comprises six compartments or bays. A slit valve (not shown) may be located between adjacent process modules, such as those shown in FIG. 1A, to isolate the adjacent process modules from one another. Each of the process modules, such as those shown in FIG. 1A, may be separately vented to atmospheric pressure as may be appropriate for maintenance, for example. Each compartment of a process module may be separately configured as a sputtering compartment, a pump compartment, a compartment having some other purpose, or even a compartment that is unused. Different target materials may be used in different sputtering compartments and different electrical configurations may also be used. For example, both AC power and DC power may be used for sputtering.

In the process module 106 illustrated in FIG. 2, a pump compartment 203 is located at one end of the process module and a pump compartment 205 is located at the other end of the process module. Such an arrangement may be used to reduce gas flow between the process module 106 and any process module that is located at an end of the process module 106. As also illustrated in FIG. 2, sputtering compartments A-D are located between the two pump compartments 203 and 205. Sputtering compartment B may be a sputtering compartment that employs a planar magnetron, as shown. In a typical planar sputtering application, a small amount of an expensive material or a high value material is sputtered from at least one planar magnetron in the compartment. The material is generally such that a cylindrical target comprising the material would be undesirably or prohibitively expensive. Examples of such a material include silver (Ag) and nickel-chromium. Sputtering compartment C may be an AC-powered sputtering compartment and sputtering compartment D may be a DC-powered sputtering compartment, as shown.

The cabling that is used to provide power from the power supply unit to the magnetron for one compartment configuration may be different than that used to do the same for a different compartment configuration. By way of example, a cable that is used to provide AC power for AC sputtering is generally different than a cable that is used to provide DC power for DC sputtering. Further by way of example, the number of cable assemblies used for one particular compartment configuration may vary significantly from the number used for another compartment configuration, such as from one cable assembly for a compartment calling for up to about 70 amperes of current for a relatively low-power application, for example, to up to about six cable assemblies for a compartment calling for up to about 400 amperes of current for a relatively high-power application, for example. Generally, it is not economical to associate a six-cable assembly with every compartment (particularly for those compartments most remote relative to the external power supply unit, for example), although failure to do so may be limiting in terms of flexibility of the coating system as a whole. Still further by way of example, cabling may vary according to the location of a particular sputtering compartment in the coating system. For example, where a sputtering compartment is near one end of a coater, an appropriately long cable, such as one extending over 100 feet, for example, may be used, and where a sputtering compartment is near the point where the cable conduit or the cable wire-way reaches the coater, an appropriately short cable may be used. In some coating systems, all cables are made long enough to reach all compartments, although this may add expense, may contribute to RF noise or interference, and/or may result in considerable power loss between the power supply unit(s) and the sputtering compartment(s). In some coating systems, each cable may be customized according to the configuration of the sputtering compartment and may not be interchangeable with another cable.

Sometimes a coating system is reconfigured such that sputtering of a particular material that might have taken place in a particular compartment might now take place in a different compartment. Such a reconfiguration may involve moving the lid assembly, as may be associated with a particular target, from its original compartment to a different or new compartment. Such a reconfiguration may further involve associating the power-supply cabling that was associated with original compartment with the new compartment without changing the power supply unit or its location. Alternatively, such a reconfiguration may further involve rerouting the power-supply cabling to a new power supply. Problems often occur during such reconfigurations. The original cabling may be too short for the new location or the cabling may be misconnected. For example, a power supply unit may be connected to a wrong or an unintended magnetron, a magnetron may be connected to a wrong or an unintended power supply, a wrong or an unintended cable may be used, and/or the like. Such a misconnection is generally undesirable, as it may produce undesirable processing conditions, may lead to a safety problem, and/or the like. Merely by way of example, if a power supply unit were to unintentionally provide sputtering power to a magnetron that is undergoing maintenance, unsafe conditions might result.

FIG. 3 is a schematic, block-diagram illustration of a system in which cables 321-324 associated with power supply units 301-304, respectively, are connected to magnetrons 311-314 of sputtering compartments A-D of FIG. 2. In this illustration, all of the power supply units 301-304 are connected to a common electrical supply. The common electrical supply may be a nominal 380-volt or 480-volt (as shown), 3-phase AC supply. Each of cables 321-324 is dedicated to each of power supply units 301-304, respectively. These cables are generally not interchangeable. By mistake or error, power supply unit 303 is connected to magnetron 314, rather than magnetron 313 as intended, via cable 323, and power supply unit 304 is connected to magnetron 313, rather than magnetron 314 as intended, via cable 324.

As illustrated in FIG. 3, controller 330 is connected to each power supply unit 301-304 and to each magnetron 311-314. Mapping information stored by controller 330 indicates the relationships between power supply units 301-304 and magnetrons 311-314. This information is usually manually entered by the operator. For example, controller 330 may indicate that power supply unit 303 is connected to magnetron 313 as this is the correct, desired, or anticipated configuration. The anticipated configuration differs from the actual configuration shown because of an error in cabling. In view of the anticipated configuration, controller 330 will be used as if it were capable of sending command signals to power supply unit 303 in order to control the electrical supply to magnetron 313. In view of the actual configuration, however, the command signals sent by controller 330 to power supply unit 303 will actually control the electrical supply to magnetron 314, rather than magnetron 313. This may cause errors in processing and may present a safety hazard. For example, it may be desirable to turn off magnetron 314, perhaps for maintenance, by way of controller 330 or by switching off power supply unit 304 that is erroneously associated with magnetron 313. In this example, power may still be sent to magnetron 314 because power supply unit 303 is erroneously connected to it via cable 323. This may result in harm to a technician working on magnetron 314 during maintenance, for example. This may also result in damage to equipment. For example, if power supply unit 303 is an AC power supply unit connected to magnetron 314 via a DC cable 323, the DC cable 323 may be damaged when it receives AC power from the AC power supply unit.

Development of apparatus, systems and methods for coating substrates is generally desirable.

### SUMMARY

A module, such as a pump module or a sputtering module, may comprise a lid assembly that comprises a lid sufficient to fit or to cover an opening of a compartment, such as a pump compartment or a sputtering compartment, of a coating system, such as a modular coating system. When the module is a sputtering module, it may comprise a power supply unit and may be sufficient for receiving an electrical input, such as a standard electrical input, for example, and for delivering an electric output sufficient for sputtering in a sputtering compartment. When the module is a pump module, it may comprise at least one pump and may be sufficient for receiving an electrical input sufficient for operating the pump or pumps. Various connections between the module, any external supplies, components or devices, and the compartment may be made automatically and/or manually. A control connection between the module and the compartment may be such that an external controller is able to recognize a particular module that is associated with a particular compartment of the coating system.

A sputtering module may take the form of a single physical unit that comprises a power supply unit and a magnetron. By way of example, a power supply unit and a magnetron may be physically associated with or attached to a top and a bottom, respectively, of the lid of the lid assembly of the sputtering module. Further by way of example, when the lid assembly is placed on top of a compartment in an appropriate manner, the power supply unit may be supported above the compartment by the lid, the magnetron may be supported within the compartment by the lid, and the lid may be sufficient to seal the top of the compartment. The sputtering module may further comprise a housing or cover that at least partially encloses components associated with the top of the lid, such as the power supply unit and any connection cable linking the power supply unit and the magnetron, for example, such that undesirable noise or interference that may be associated with various module components may be more or less confined within the cover, for example.

The sputtering module may be moved from one compartment to another compartment of a coater by moving the lid assembly in any appropriate manner, such as via the housing or the cover of the module. As the power supply unit and the magnetron may be associated with a single physical unit, it may be relatively easy to avoid connecting another power supply with the magnetron, or another magnetron with the power supply unit, in an undesirable manner, following such movement of the module or following any reconfiguration of the coater. Further, as the power supply unit and the magnetron may be associated with a single physical unit, it may not be necessary to use a remote power supply and associated cabling. As such, a coating system may be relatively economical in terms of overall footprint and overall cost, relatively simple in terms of configuration, and/or relatively safe in terms of operation or maintenance.

A number of sputtering modules of a coating system may use a common electrical supply. In such a case, the internal power supply unit of an individual sputtering module may convert electrical input from the common electrical supply to an appropriate electrical output, such as an electrical output that is appropriate for the magnetron of the sputtering module or the sputtering process associated with the sputtering module, for example. The common electrical supply may be associated with an individual sputtering compartment of the coater. A sputtering module may be connected to the common electrical supply associated with an individual sputtering compartment automatically, upon appropriate positioning of the module and the compartment relative to one another. Other appropriate connections associated with the module and the compartment, such as connections associated with a supply of a cooling medium, for example, may be automatic. Any of the foregoing or other appropriate connections may be manual and/or automatic, for example.

A pump module may be associated with a compartment of a coater. Such a pump module may comprise at least one pump sufficient to provide vacuum to a compartment, for example. The pump or pumps may be physically associated with or attached to a top of the lid of the lid assembly and may be at least partially enclosed by a housing or a cover. By way of example, when the lid assembly is placed on top of a compartment in an appropriate manner, the pump or pumps may be supported above the compartment by the lid and the lid may be sufficient to seal the top of the compartment. The pump module may be moved from one compartment to another compartment of a coater by moving the lid assembly in any appropriate manner, such as via the housing or the cover of the module. An appropriate connection between the pump module and a backing pump, such as a foreline, for example, may be provided. A pump module may be connected to a foreline automatically, upon appropriate positioning of the module and the compartment relative to one another. Other appropriate connections associated with the module and the compartment may be automatic. Any of the foregoing or other appropriate connections may be manual and/or automatic, for example.

A central controller may be associated with an individual compartment of a coater via a control connector, such as a dedicated cable, for example. The central controller may be associated with each of the individual compartments of a coater via each of a number of individual compartment-dedicated cables, for example. The cable may be connected to a module, be it a sputtering module or a pumping module, that is appropriately associated with or positioned relative to the individual compartment. The module may be associated with a unique identifier by which the controller may recognize the module, and thereby associate the module with a particular compartment. In such a system, it may not be necessary to otherwise provide the controller with mapping data, such as via manual data entry, for example, which may be vulnerable or prone to error.

These and various other aspects, features, and embodiments are further described herein.

### BRIEF DESCRIPTION OF DRAWINGS

A description of various aspects, features and embodiments is provided herein with reference to the accompanying drawings, which are briefly described below. The drawings are illustrative and are not necessarily drawn to scale. The drawings illustrate various background material or various aspects or features and may illustrate one or more embodiment(s) or example(s) in whole or in part. A reference numeral, letter, and/or symbol that is used in one drawing to refer to a particular element or feature may be used in another drawing to refer to a like element or feature.

FIG. 1A is a schematic, elevated side-view illustration of a coating system.

FIG. 1B is a schematic illustration of a cross-section of a process module of the coating system of FIG. 1A, wherein the cross-section is in a plane that is perpendicular to a direction of substrate travel. FIG. 1A and FIG. 1B may be collectively referred to herein as FIG. 1.

FIG. 2 is a schematic illustration of a cross-section of a process module of the coating system of FIG. 1A, wherein the cross-section is in a plane that is parallel to a direction of substrate travel.

FIG. 3 is a schematic, block-diagram illustration of a system for providing and controlling power to compartments of the process module of FIG. 2.

FIG. 4 is a schematic illustration of a cross-section of a sputtering compartment and a sputtering module described herein, wherein the cross-section is in a plane that is perpendicular to a direction of substrate travel.

FIG. 5A is a schematic illustration of a cross-section of a sputtering compartment and a sputtering module described herein, wherein the cross-section is in a plane that is perpendicular to a direction of substrate travel.

FIG. 5B is an upper-elevation, side-view illustration of portion of a sputtering compartment and a portion of a sputtering module, such as those of FIG. 5A, described herein.

FIG. 5C is a lower-elevation, side-view illustration of portion of a sputtering compartment and a portion of a sputtering module, such as those of FIG. 5A, described herein.

FIG. 5D is an upper-elevation, side-view illustration of portion of a sputtering compartment and a portion of a sputtering module, such as those of FIG. 5A, described herein.

FIG. 5E is a lower-elevation, side-view illustration of portion of a sputtering compartment and a portion of a sputtering module, such as those of FIG. 5A, described herein.

FIG. 5A, FIG. 5B, FIG. 5C, FIG. 5D and FIG. 5E may be collectively referred to herein as FIG. 5.

FIG. 6A is a schematic illustration of cross-section of a portion of a coating system in which a sputtering module may be moved and a pump module may be moved, as described herein, wherein the cross-section is in a plane that is parallel to a direction of substrate travel.

FIG. 6B is a schematic illustration of a portion of a coating system comprising a sputtering module and a pump module described herein, as may result from movement such as that associated with FIG. 6A, wherein the cross-section is in a plane that is parallel to a direction of substrate travel.

FIG. 6C is a schematic illustration of cross-section of a portion of a coating system comprising a pump module and a compartment, such as those associated with FIG. 6B, described herein, wherein the cross-section is in a plane that is perpendicular to a direction of substrate travel.

FIG. 6A, FIG. 6B and FIG. 6C may be collectively referred to herein as FIG. 6.

FIG. 7 is a schematic, block-diagram illustration of a system for providing and controlling power to process modules, as described herein.

FIG. 8 is an upper-elevation, side-view illustration of a sputtering module, as described herein.

FIG. 9A is a lower-elevation, side-view illustration of a planar magnetron-associated sputtering module described herein.

FIG. 9B is an upper-elevation, side-view illustration of a cross-section of a portion of a planar magnetron-associated sputtering module described herein.

FIG. 9A and FIG. 9B may be collectively referred to herein as FIG. 9.

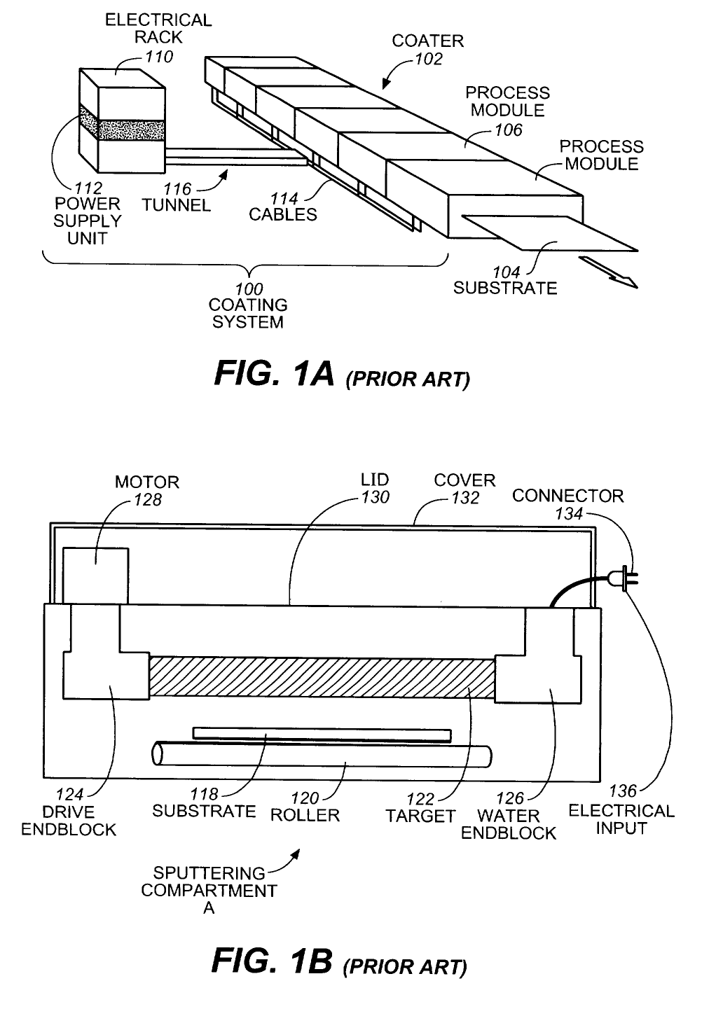

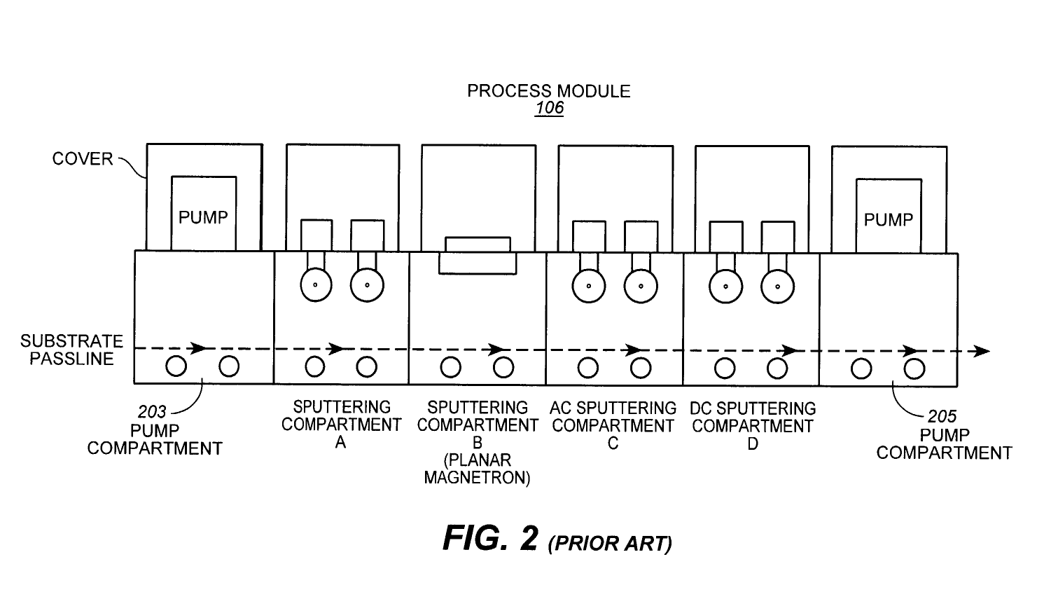

### DESCRIPTION

In this application, it will be understood that a word appearing in the singular encompasses its plural counterpart, and a word appearing in the plural encompasses its singular counterpart, unless implicitly or explicitly understood or stated otherwise. Further, it will be understood that for any given component described, any of the possible candidates or alternatives listed for that component, may generally be used individually or in any combination with one another, unless implicitly or explicitly understood or stated otherwise. Additionally, it will be understood that any list of such candidates or alternatives, is merely illustrative, not limiting, unless implicitly or explicitly understood or stated otherwise. Still further, it will be understood that any figure or number or amount presented is approximate, and that any numerical range includes the minimum number and the maximum number defining the range, whether the word “inclusive” or the like is employed or not, unless implicitly or explicitly understood or stated otherwise. Yet further, it will be understood that any heading employed is by way of convenience, not by way of limitation. Additionally, it will be understood that any permissive, open, or open-ended language encompasses any relatively permissive to restrictive language, less open to closed language, or less open-ended to closed-ended language, respectively, unless implicitly or explicitly understood or stated otherwise. Merely by way of example, the word “comprising” may encompass “comprising”—, “consisting essentially of”—, and/or “consisting of”—type language.

Various terms are generally described or used to facilitate understanding. It will be understood that a corresponding general description or use of these various terms applies to corresponding linguistic or grammatical variations or forms of these various terms. It will also be understood that a general description or use or a corresponding general description or use of any term may not apply or may not fully apply when the term is used in a non-general or more specific manner. It will also be understood that the terminology used, or the descriptions thereof, for the description of particular embodiments, is not limiting. It will further be understood that embodiments described or applications described, are not limiting, as such may vary.

A modular sputtering system comprising a series of compartments, such as a number of processing or coating compartments and a number of pumping compartments, may be configured in various ways, such as various ways described in co-pending U.S. patent application Ser. No. ______ of Michael Robert Perata et al., entitled “Apparatus and Method for Coating Substrates with Approximate Process Isolation” and filed on May 8, 2006, which is incorporated herein in its entirety by this reference, merely by way of example. A modular sputtering system may be relatively flexible in terms of configuration or reconfiguration, for example.

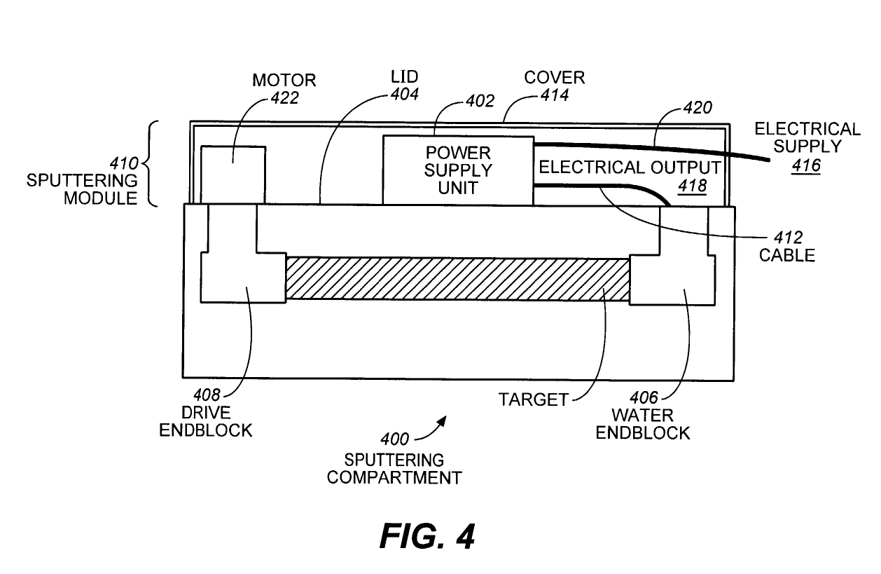

An embodiment of a sputtering compartment and a sputtering module suitable for use in a modular sputtering system is now described in relation to FIG. 4. A cross-section of such a sputtering compartment 400 and a sputtering module 410 comprising a power supply unit 402 that is connected or mounted to a top of lid 404 is schematically illustrated in FIG. 4. Merely by way of example, the power supply unit 402 may be disposed relative to the topside of lid 404 between where water endblock 406 and drive endblock 408 are disposed relative to the underside of lid 404, as shown. When power supply unit 402 is located near or adjacent to water endblock 406, as shown, the risk of connecting power supply unit 402 to the wrong endblock may be reduced or eliminated. The sputtering module 410 may further comprise a motor 422, connected or mounted to the top of lid 404, that is associated with drive endblock 408. The sputtering module 410 further comprises an electrical input device and an electrical output device associated with power supply unit 402, as further described herein, and may further comprise a housing or cover 414, as shown, that at least partially encloses various components of the sputtering module.

The electrical output device associated with power supply unit 402 may comprise at least one cable 412 that communicates electrical output 418 of power supply unit 402 to water endblock 406. Cable 412 may be connected in a manner that allows power supply unit 402 and endblock 406 to be easily disconnected. When power supply unit 402 and endblock 406 are not connected or are disconnected, the power supply unit may be connected to an endblock of a different sputtering module. Cable 412 may be relatively short, such as three feet or less, for example. In a sputtering module 410 in which cable 412 is sufficiently short, radio frequency (RF) noise or interference and/or transmission-related power loss associated with cable 412 may be reduced or eliminated, and costs may be reduced, relative to a sputtering compartment employing relatively longer cabling associated with a remote power supply unit, for example. Cable 412 may be at least partially enclosed by housing or cover 414, as shown, which may also reduce or eliminate communication of RF noise or interference beyond the housing or the cover and/or interference with other equipment.

The electric input device associated with power supply unit 402 may comprise a cable 420, which may be at least partially enclosed by housing or cover 414, as shown, for communicating electrical input from electrical supply 416 to the power supply unit. Electrical supply 416 is external relative to sputtering module 410. Multiple sputtering modules or all sputtering modules associated with a coater may adapted for use with electrical supply 416. For example, sputtering modules associated with a coater may have compatible or identical cables or connectors sufficient for communication with electrical supply 416, such that one such sputtering module may be exchanged for another. Cable 420, which is used to supply the electric input to the power supply unit 402 associated with a compartment 400, may be sized to supply the maximum power that is likely to be needed by the compartment, or any compartment in the coater. A common electrical supply may be associated with different compartments or magnetrons, and at least one circuit breaker and/or at least one interlock circuit may be associated with each compartment or magnetron. Components for the circuit breaker(s) and/or for the interlock circuit(s) are generally available from a number of commercial sources, such as Rockwell Automation Allen-Bradley & Rockwell Software Brands (Milwaukee, Wis.), Siemens Corporation (New York City, N.Y.), Square D brand of Schneider Electric SA (Reuil-Malmaison, France), and Moeller Electric Corporation (Houston, Tex.), merely by way of example, and the assembly of same may be in any appropriate manner, such as any known manner, merely by way of example. Power supplies incorporating one or more circuit breaker(s) and/or interlock circuit(s) are generally commercially available, or may be assembled in any appropriate manner. At least one electrical filter (not shown), at least one electrical trap (not shown), and/or any combination of same, may be used to reduce or to prevent the migration of RF noise or interference that may be associated with sputtering module 410 to electrical supply 416. Components for the filter(s) and/or trap(s) are generally available from a number of commercial sources, and the assembly of same may be in any appropriate manner, such as any known manner, merely by way of example. Power supplies incorporating one or more filter(s) and/or traps(s) are generally commercially available, or may be assembled in any appropriate manner.

Electrical supply 416 may be an unmodified house supply, such as a standard three-phase AC supply, for example. Merely by way of example, the electrical supply may be a three-phase AC supply from about 380 volts to about 600 volts, and about 50 to about 60 Hertz. Further merely by way of example, the electrical supply may be a 480-volts, 60-Hertz supply in the United States and a 380-volts, 50-Hertz supply elsewhere. Power supply unit 402 may be sufficient to convert electrical input from electrical supply 416 to electrical output 418 that may be used for sputtering. By way of example, power supply unit 402 may convert a 480-volts, 60-Hertz AC input to a DC output of about 300 volts to about 900 volts or an AC output of about 350 volts to about 1000 volts. AC frequencies suitable for sputtering with cylindrical cathodes may be in a range of about 30 kiloHertz to about 90 kiloHertz.

Power supply unit 402 may comprise at least one feedback control circuit sufficient for the maintenance or the modification of output 418 based on a set or predetermined point or a set or predetermined range. For example, if the output is in accord with a set point or a set range, the power supply unit is sufficient to maintain the output, and if the output is different or deviates from a set point or a set range, the power supply is sufficient to adjust or to modify the output such that it is in accord with the set point or the set range. Power supply unit 402 may comprise at least one storage device or memory device for storing such a set point or a set range, or may comprise a connection with an external storage device or memory device. By way of example, power supply unit 402 may have a power set point, a power set range, a current set point, a current set range, a voltage set point, and/or a voltage set range. Any of such set points or set ranges may be provided to power supply unit 402 by a controller (not shown) of the coating system. If the output 418 is above or below the set point or outside the set range, the feedback control circuit of the power supply unit 402 makes appropriate changes to bring the output back to the set point or a level associated with the set range. The feedback control circuit of the power supply unit 402 may comprise at least one insulated gate bipolar transistor (IGBT) and/or at least one power device sufficient to modify the electrical supply and to provide a controlled output. Power supply unit 402 may comprise at least one arc suppression circuit sufficient to detect an arc in a sputtering compartment and to respond effectively, such as by cutting off power for a short period, for example. An example of an arc detection and diversion circuit is provided in U.S. Pat. No. 5,241,152, which is incorporated in its entirety herein by this reference. Components for the feedback control(s), the storage/memory device(s), the insulated gate bipolar transistor(s), the modifying power device(s), and/or the arc suppression circuit(s), are generally commercially available, and the assembly of same may be in any appropriate manner, such as any known manner, merely by way of example. Power supplies incorporating one or more of these component(s) are generally commercially available, or may be assembled in any appropriate manner. An example of a commercial source for various power supply related components is Advanced Energy, Inc. (Fort Collins, Colo.).

When the power supply unit 402 is a DC power supply unit, it may comprise rectification circuitry sufficient to convert AC to DC and/or may comprise voltage control circuitry sufficient to control DC output voltage. For example, power supply unit 402 may comprise a transformer sufficient to convert incoming AC to an appropriate voltage. Power supply unit 402 may generate a significant amount of heat, such that adequate cooling is desirable or necessary. Suitable cooling for the power supply unit 402 may be provided by an appropriate cooling medium or fluid, such as air or water, for example. In a compartment in which a target is cooled by water, such as via a water endblck 406, it may be desirable or convenient to use water to cool the power supply unit 402.

Power supply unit 402 is sufficient to provide power to sputter compartment 400 for a sputtering application. As such, no remote power supply, electrical rack, or cabinet is needed in association with sputtering compartment 400. A coater employing a sputtering module 410 in association with a sputtering compartment 400 or several such sputtering modules in association with several such sputtering compartments, respectively, may thus be relatively economical in terms of overall system footprint and cost and relatively easy to configure or reconfigure.

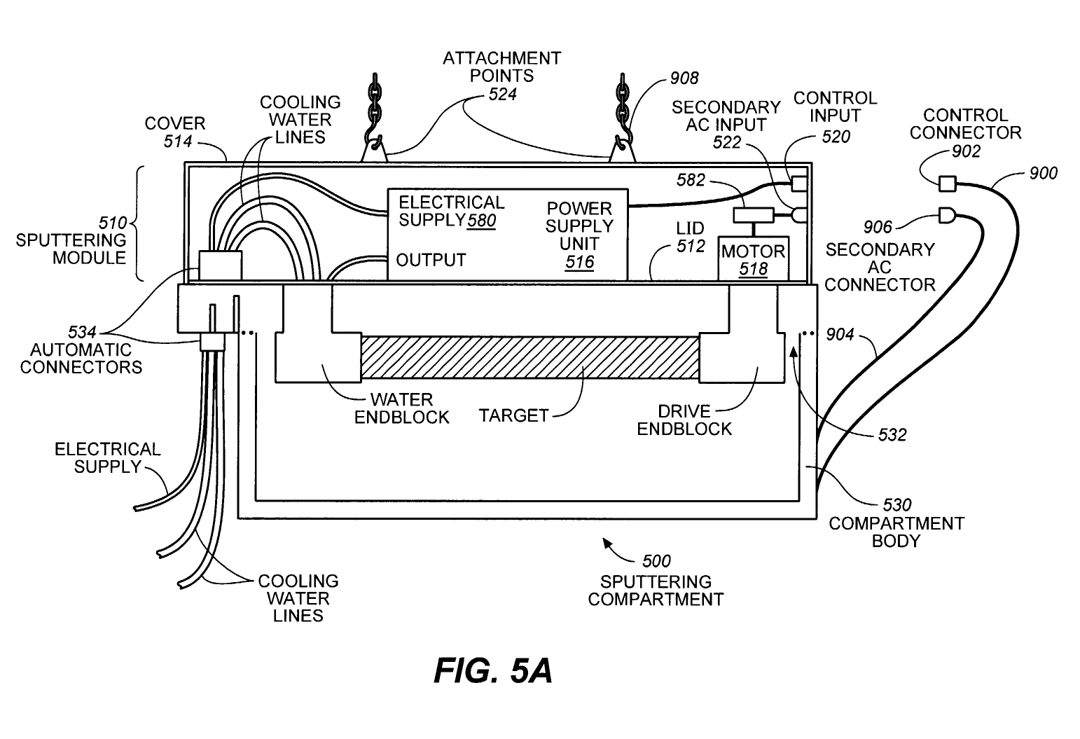

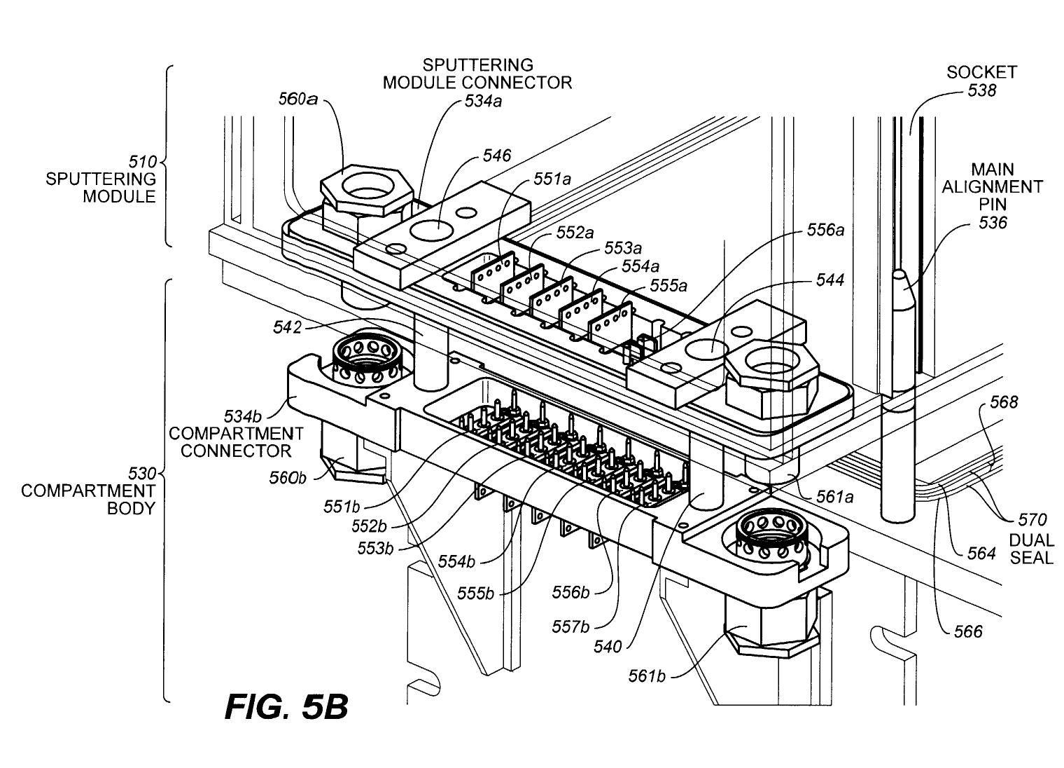

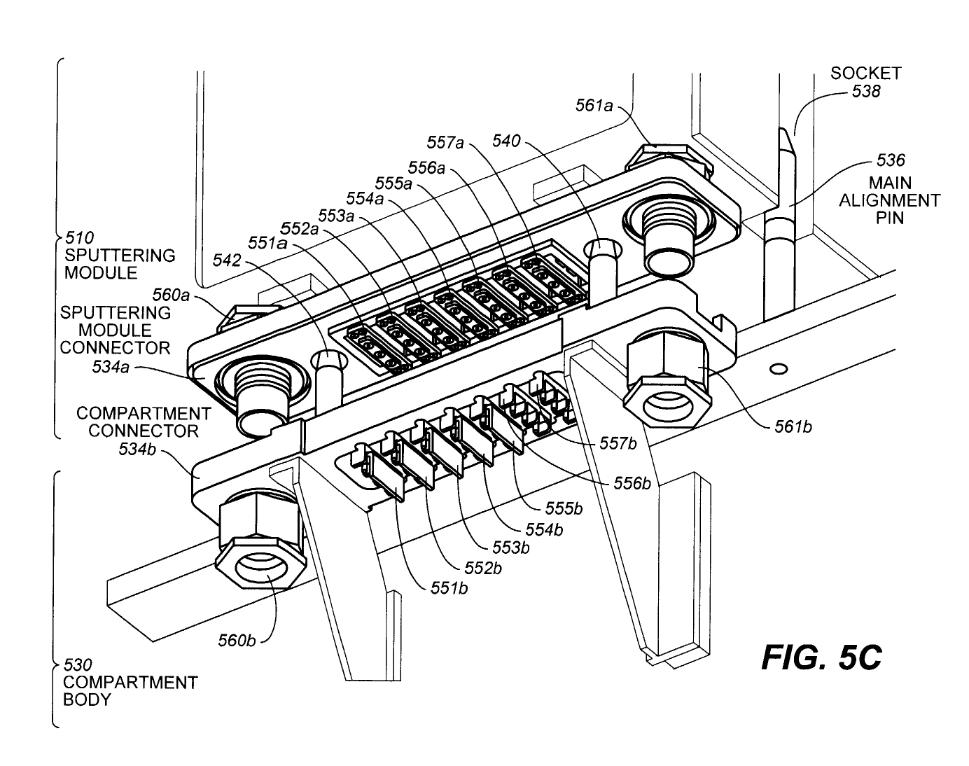

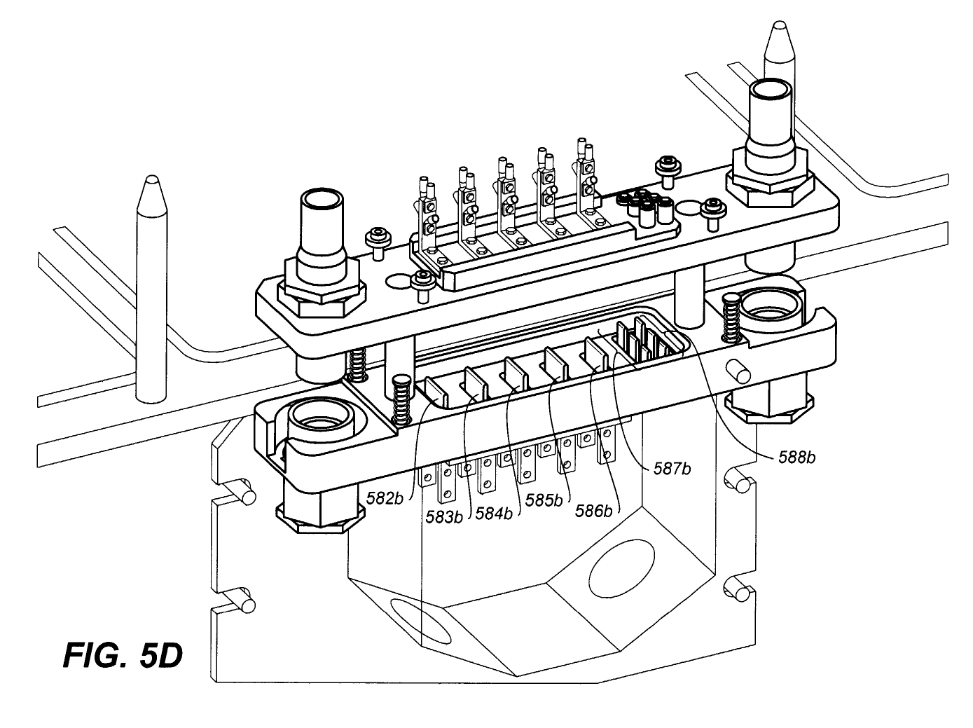

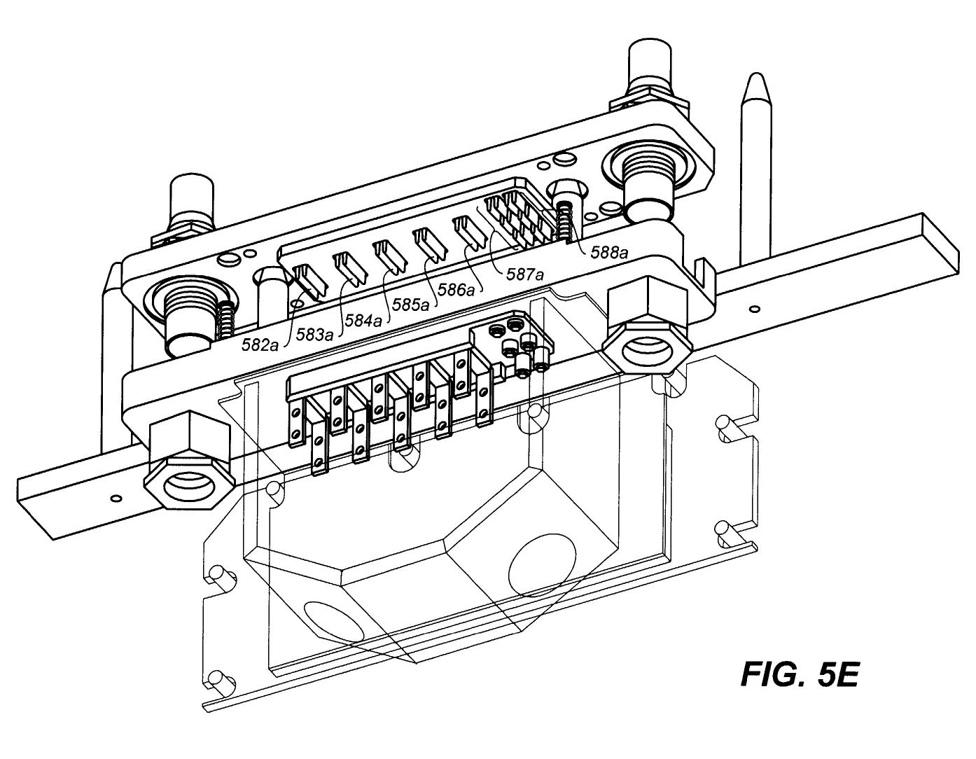

An embodiment of a sputtering compartment and a sputtering module suitable for use in a modular sputtering system is now described in relation to FIG. 5. A cross-section of such a sputtering compartment 500, comprising a compartment body, and a sputtering module 510, comprising a power supply unit 516 that is connected or mounted to a top of lid 512, is schematically illustrated in FIG. 5A. In the schematic illustration, sputtering module 510 is shown as it is being moved relative to sputtering compartment 500, as may be appropriate for the reconfiguration of a coater in which sputtering module 510 is moved from one compartment, such as sputtering compartment 500, to another compartment of the coater, for example. Sputtering modules may be designed to be capable of such movement, such that a sputtering module that may be associated with one compartment may easily be moved from that compartment, such as to another compartment of a coater, for example, and/or for interchangeability, such that a sputtering module that may be associated with one compartment may be interchanged with, exchanged for, or replaced by another sputtering module that may be associated with another compartment of a coater, for example.

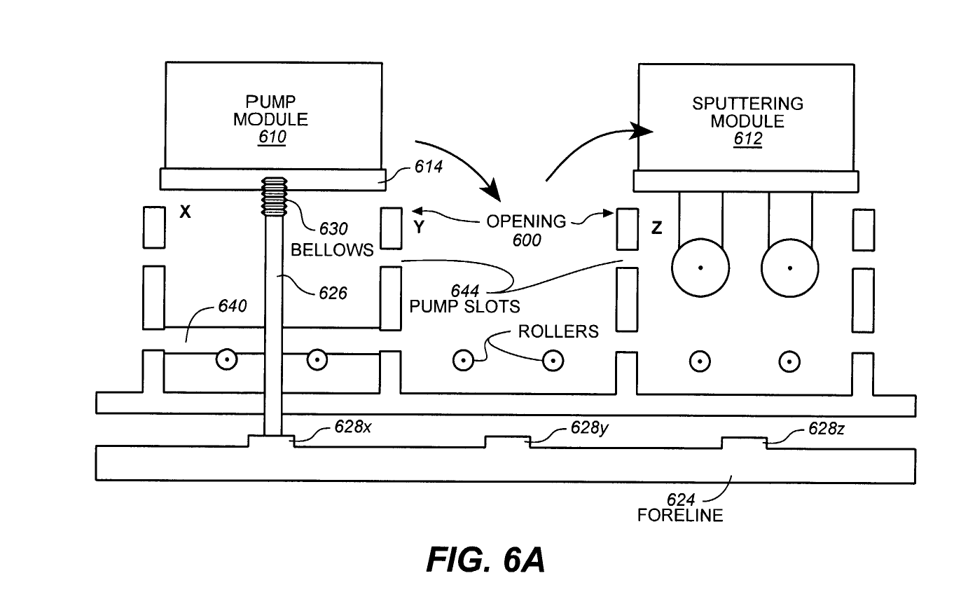

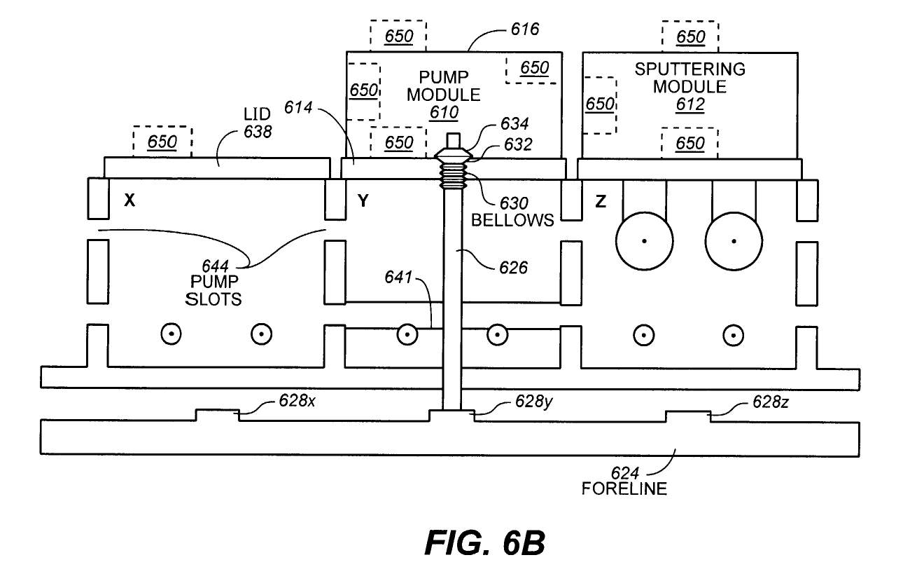

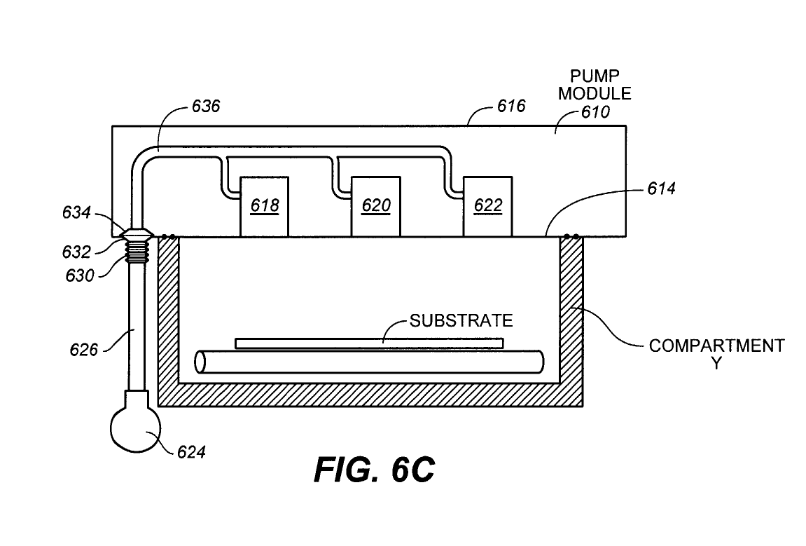

It will be understood that power supply unit 402 or 516 may be physically associated with the lid 404 or 512, respectively, as shown in FIG. 4 or FIG. 5A, respectively, in any appropriate manner, such as directly, indirectly, immediately and/or proximally, for example. For example, power supply unit 516 may be physically associated with the lid 512 via housing or cover 514, in any appropriate manner. Merely by way of example, power supply unit 516 may be attached to or mounted on a top or side of housing or cover 514, which is physically associated with the lid 512. Further by way of example, power supply unit 516 may be physically associated with a lid (not shown), which may be similar to lid 512, for example, that is associated with a nearby compartment (not shown), such as an adjacent compartment, a compartment located a number of compartments away, such as up to about four compartments away, for example, in any appropriate manner. The power supply unit 516 may be so associated with a lid of another compartment in any of the ways previously described in relation to lid 512 and housing or cover 514, for example. Still further by way of example, power supply unit 516 may be physically associated with another location on the coater, whether directly or indirectly. For example, power supply unit 516 may be physically associated with a lid or a cover that is located anywhere on the coater. Examples of appropriate locations for power supply unit 650 that may be associated with sputtering module 612 are shown in dashed lines in FIG. 6B, by way of illustration, not limitation. In general, any possible, practical, feasible, and/or convenient location associated with the coater may be employed. In general, the location is other than a remote, off-coater location. It will be understood that any connection or cabling may be adjusted in any appropriate manner to accommodate the location of the power supply unit relative to the appropriate compartment.

In general, when a sputtering module is moved from a compartment of a coater, the process module in which the compartment is located is vented to atmospheric pressure, and any connections, such as any manually manipulated connections, for example, to the sputtering module are disconnected. By way of example, a cable 900 that facilitates communication between a sputtering module 510 and a controller (not shown) may be disconnected. In the illustration of FIG. 5A, for example, a control connector 902 associated with such a cable 900 may be removed from a control input 520 of sputtering module 510. As shown in FIG. 5A, when the control connector 900 is connected to control input 520, it is in communication with power supply unit 516 and a sputter module control 582, which is in communication with motor 518. Sputter module control 582 may be used to control operation of at least one motor that may be associated with at least one endblock and to monitor at least one interlock circuit that may be associated with sputtering module 510, such as an interlock circuit associated with target rotation, motor torque, such as high or low motor torque, for example, endblock vacuum, such as vacuum leakage, for example, endblock cooling fluid flow, such as air flow, water flow, or cooling fluid leakage, for example, and safety cover presence or integrity, for example. Sputtering module control 582 may be used to communicate information associated with the interlock circuit to the main control and/or user interface of the coating system, for example.

Further by way of example, a cable 904 that facilitates communication of control power, such as low-voltage control power, for example, between a sputtering module 510 and a secondary electrical supply (not shown), such as a 240-volt or a 120-volt AC supply, for example, may be disconnected. In the illustration of FIG. 5A, for example, a secondary AC connector 906 associated with such a cable 904 may be removed from a secondary AC input 522 of sputtering module 510. As shown in FIG. 5A, when the secondary AC connector 906 is connected to secondary AC input 522, it is optionally (as indicated by a dashed line) in communication with power supply unit 516 and is in communication with a sputter module control 582, which is in communication with motor 518. When a secondary electrical supply is employed, it may be separate from a main electrical supply 580 that provides electrical input for sputtering, as shown. The secondary supply may be used to run at least one component associated with the sputtering module that has a relatively low power requirement. Examples of such components include motor 518 that may be used to rotate drive endblock and logical components (not shown) of sputtering module 510.

Once a sputtering compartment 500 is vented to atmosphere and appropriate connections are disconnected, sputtering module 510 may be lifted away from compartment body 530 by any suitable means or method. By way of example, as shown in the illustration of FIG. 5A, at least one attachment device 524, such as two flanges, each provided with a hole, for example, may be connected to or mounted on a housing or a cover 514 of sputtering module 510, and at least one hoist device 908, such as two suspended hooks, each sufficient for engaging a hole associated with a flange, for example, may be employed to facilitate the lifting of the sputtering module from the compartment body 530. The hoist device 908 may be sufficient to not only lift sputtering module 510 in a manner such as that just described, for example, but also to move the sputtering module to another location, and/or to lower the sputtering module. In this or any other suitable manner, sputtering module 510 may be disposed above a sputtering compartment and may be lowered such that it is placed on top of a compartment body of that sputtering compartment. In the illustration of FIG. 5A, sputtering module 520 is shown in a raised position relative to compartment body 530, such that it may be moved away from that compartment body, for example, perhaps to a location of another compartment body.

Sputtering compartment 500 and sputtering module 510 may be designed or configured such that when the sputtering module is disposed sufficiently above compartment body 530, or raised sufficiently relative to compartment body 530, at least one connection therebetween is automatically disconnected. Sputtering compartment 500 and sputtering module 510 may be designed or configured such that when the sputtering module is disposed sufficiently to contact compartment body 530, or lowered sufficiently relative to compartment body 530, at least one connection therebetween is automatically made. Such a connection may be facilitated by automatic connectors, such as the automatic connectors 534 shown in FIG. 5A.

Automatic connectors 534 are now described in relation to FIG. 5B and FIG. 5C, the former providing a view from above automatic connectors 534 of FIG. 5A and the latter providing a view from below automatic connectors 534 of FIG. 5A. As shown in these two figures, a main alignment pin 536 extends upwards from the compartment body 530 to engage a corresponding socket 538 in sputtering module 510. Another main alignment pin (not shown) may extend from another location, such as an opposite end, for example, of the compartment body 530 to engage a corresponding socket (not shown) in sputtering module 510. It will be understood that the location of any of the pins could be associated with the sputtering module 510 and any of the corresponding sockets could be associated with the compartment body 530. It will be further understood that the location of any of the pins may be any suitable location and the corresponding location of any of the corresponding sockets may be any suitable corresponding location. When the main alignment pins and the corresponding sockets are appropriately engaged, sputtering module 510 and compartment body 530 are sufficiently aligned, such that lid 512 of sputtering module 510 and opening 532 of compartment body 530 (see FIG. 5A) and automatic connectors 534 of sputtering module 510 and of compartment body 530 (see FIG. 5A) are sufficiently aligned for operability and appropriate connection, for example.

In the illustrations of FIG. 5B and FIG. 5C, automatic connectors 534 of FIG. 5A are shown as comprising connector 534a associated with or attached to sputtering module 510 and corresponding connector 534b associated with or attached to compartment body 530. It will be understood that the location of connector 534a could be associated with the compartment body 530 and corresponding connector 534b could be associated with the sputtering module 510. It will be further understood that the location of connector 534a may be any suitable location and the corresponding location of corresponding connector 524b may be any suitable corresponding location. When main alignment pins and the corresponding sockets are appropriately engaged, connector 534a and connector 534b are at least roughly or sufficiently aligned.

As illustrated in FIG. 5B and FIG. 5C, alignment pins 540 and 542 extend from connector 534b in an upward direction and corresponding sockets 544 and 546 are associated with connector 534a. Alignment pins 540 and 542 are sufficient to engage corresponding sockets 544 and 546, respectively, such that connector 534a and connector 534b are sufficiently aligned, such as finely aligned, for example. As in the cases of various pins and sockets described above, the locations of the pins and sockets just described may be any suitable locations. Connector 534a may have some freedom of lateral movement with respect to the rest of sputtering module 510, such that connector 534a may be guided into position by alignment pins 540 and 542, for example. Additional alignment pins, such as relatively small alignment pins, may be used in association with connector 534b and additional corresponding sockets may be used in association with connector 534a for alignment purposes. As in the cases of various pins and sockets described above, the locations of the additional pins and additional corresponding sockets just described may be any suitable locations.

In the illustrations of FIG. 5B and FIG. 5C, seven electrically isolated pairs 551-557, collectively, of connector elements 551a-557a associated with connector 534a and corresponding connector elements 551b-557b associated with connector 534b, respectively, are shown. Each pair of connector elements comprises three electrical pins and corresponding sockets and two alignment pins and corresponding sockets. Other numbers, configurations and/or combinations of connector elements, electrical pins, alignment pins, and corresponding sockets are possible and contemplated herein. For example, as in the cases of various pins and sockets described above, the locations of connector elements, electrical pins, alignment pins, and corresponding sockets just described may be any suitable locations. Connector elements 551a-557a and connector elements 551b-557b may have some freedom of lateral movement, such that the alignment pins and the corresponding sockets cause corresponding connector elements to move into position as they are brought together. The separate pairs of connector elements may allow for a range of different connection options, such as any of those further described herein, for example.

In a case in which a remote, off-coater power supply is used in association with a sputtering compartment, such as compartment 500 of FIG. 5, for example, the connector elements just described may be such that the off-coater power supply (not shown) may be automatically connected to an endblock, such as the water endblock, associated with a lid of the compartment. For example, in FIG. 5A, the connection of electrical supply 580 to the automatic connector 534 may be replaced with a connection of an off-coater power supply (not shown) to the automatic connector 534 via an appropriate cable or cable assembly. In a case in which the power supply that is used in association with a sputtering compartment, such as compartment 500 of FIG. 5, is physically associated with a nearby or an adjacent compartment, such as via a module, a lid, and/or a housing or a cover associated with an adjacent compartment, for example, the connector elements just described may be such that the power supply (not shown) may be manually connected to an endblock, such as the water endblock, associated with a lid of the compartment. In either of the cases described above, an alteration of cover 514 that may be present may be undertaken to provide appropriate access to the water endblock for the connection just described.

In a case in which a sputtering module 514 is used in association with a sputtering compartment, such as compartment 500 of FIG. 5, a power supply 516 may be directly connected to a magnetron or a target, as shown. In such a case, an incoming electrical supply may be a common electrical supply, such as one that is used by at least one other sputtering module and/or by at least one other piece of equipment, for example, rather than being a controlled supply from a power supply unit. When a 480-volts, 3-phase common electrical supply is employed, for example, three connector elements, such as connector elements 551b-553b, for example, may be used in connection with the three AC phase sources, and an additional connector element, such as connector element 554b, for example, may be used in connection with a ground source. In such a case, all of the pins of an individual connector element of connector elements 551b-554b may be connected together, such that large currents employed may be appropriately handled, for example. In some cases, another connector element, such as connector element 555b, for example, may be used in connection with a secondary electrical supply, for example. In such a case, a single connector element may be sufficient to handle the relatively smaller currents, such as currents up to about 200 amperes, for example, associated with the secondary electrical supply, and each of the pins associated with the single connector element may be used in connection with a particular or different function or a particular or different component. For example, one pin of the connector element may be used in connection with a live or single phase, neutral source and another pin of the connector may be used in connection with a ground source.

Another connector element, such as connector element 556b, for example, or multiple connector elements if desired or needed, may be used in connection with an interlock circuit (not shown), or multiple interlock circuits. By way of example, an interlock circuit may be used to prevent operation of sputtering module 510 or to prevent the flow of electrical power to sputtering module 510, when such operation or flow may be unsafe. In a situation in which housing or cover 514 is removed for maintenance or in which no cooling water is flowing, for example, it may be unsafe or dangerous to operate sputtering module 510 or to provide electrical power to sputtering module 510. An interlock circuit generally comprises at least one component, such as a switch and/or a sensor, sufficient to indicate a condition associated with sputtering module 510, such as whether housing or cover 514 is in place, for example. If the condition is deemed safe, the interlock circuit generally returns a signal indicative of a safe condition, so that sputtering module may be operated or provided with electrical power, whether automatically, manually, or otherwise. If the condition is not deemed safe, the interlock circuit generally returns a signal indicative of an unsafe condition, so that sputtering module may not be operated or provided with electrical power, whether automatically, manually, or otherwise.

When interlock and power connections are physically separate, such that one of these connections is physically connected or disconnected separately from the other connection, there is a risk of misconnection. This is especially so when connection cabling is moved from one compartment to another. In such a case, an interlock circuit may return a false “safe” signal. When interlock and power connections are physically associated with one another, such as by being physically associated with one connector, for example, and such that one connection is physically connected and disconnected along with the other connection, there is little or no risk of misconnection. In such a case, an interlock circuit will generally not return a false “safe” signal.

At least one additional circuit may be connected via automatic connectors 534. For example, a control circuit that links sputtering module 510 to a controller (not shown) may be connected via automatic connectors 534. In some cases, all desired or necessary connections, such as power, control, and/or other connections, for example, may be made automatically. In such a case, no additional connections may be desired or necessary. It will be understood that automatic connectors 534 are not limited in terms of any particular number of connector elements, any particular pin configurations, and/or the like. Various configurations may be used, such as any configuration that may depend on the nature of the circuit or circuits to be connected or the nature of the connection or connections to be made, for example.

It will be understood that any suitable connector elements may be employed. For example, rather than the connector elements 551a-557a and corresponding connector elements 551b-557b of FIG. 5B and FIG. 5C, connector elements 582a-588a in the form of blade receivers and corresponding connector elements 582b-588b in the form of blades, as illustrated in FIG. 5D and FIG. 5E, may be employed. As shown in FIGS. 5D and 5E, some of these connector elements, such as connector elements 587a and 588a, for example, and corresponding connector elements, such as corresponding connector elements 587b and 588b, may be split up into two or more sub-elements, such as three sub-elements as shown, for example. This may be useful when a sub-element is sufficient to handle the power or electrical input it receives, such that a full element is not desirable or necessary, for example. It will be understood that any suitable connector elements may be employed for any appropriate purpose. For example, the connector element 582a and the corresponding connector element 582b may be used in connection with a ground source.

The illustrations of FIG. 5B and FIG. 5C show a pair 560, collectively, of connector element 560a associated with connector 534a and connector element 560b associated with connector 534b, and another pair 561, collectively, of connector element 561a associated with connector 534a and connector element 561b associated with connector 534b. Pair 560 is shown on one side of pairs 551-557 and pair 561 is shown on the other side of pairs 551-557. It will be understood that any of connector element 560a and 561a could be associated with the connector 534b and any of corresponding connector elements 560b and 561b could be correspondingly associated with 534a. It will be further understood that the location of any of these connector elements may be any suitable location and the corresponding location of any of these corresponding connector elements may be any suitable corresponding location. It will be still further understood that these connector elements are associated with the flow of a fluid, which typically comprises water or is water, such that they may be, by way of convenience and without limitation, referred to as water connector elements. Water connector elements 560a and 560b are relatively large, quick-disconnect, self-sealing connector elements, that when connected, form a connected (not shown) pair 560. Water connector elements 561a and 561b are relatively large, quick-disconnect, self-sealing connector elements, that when connected, form a connected (not shown) pair 561. The connected pairs are generally made by pushing water connector elements 560a and 560b together and pushing water connector elements 561a and 561b together.

When sputtering module 510 is in a sufficiently lowered position relative to sputtering compartment 500 or compartment body 530, for example, connected pairs 560 and 561 are formed, such that cooling fluid or water is free to flow through sputtering module 510. In this mode, connected pairs 560 and 561 facilitate a supply of cooling fluid or water to sputtering module 510 and a return of cooling fluid or water from sputtering module 510. When sputtering module 510 is disposed sufficiently above or lifted sufficiently relative to sputtering compartment 500 or compartment body 530, for example, pairs 560 and 561 become disconnected and the disconnected water connector elements 560a, 560b, 561a and 561b close. The closing of these elements is desirable to prevent leakage of cooling fluid or water, for example.

A cylindrical magnetron may be operated with or may require approximately 30 gallons per minute (gpm) of cooling fluid or water per target for adequate cooling at high power. By way of example, about 60 gpm of cooling fluid or water may be used in connection with a cylindrical magnetron sputtering module comprising two targets. A cooled power supply unit may be operated with or may require approximately 15 gpm of cooling fluid or water for adequate cooling. By way of example, about 75 gpm or more of cooling fluid or water may be used in connection with a cylindrical magnetron sputtering module comprising two targets and a power supply unit.

When sputtering module 510 is in a sufficiently lowered position relative to sputtering compartment 500 or compartment body 530, which may be referred to as a lowered position, and is sufficiently aligned, lid 512 extends across opening 532 in compartment body 530. In such a case, lid 512 is sufficient to seal opening 532 so that sputtering compartment 510 may be pumped appropriately, such as to a desired level of vacuum, for example. Any appropriate seal may be employed, such as a single seal or a double seal, for example. An appropriate seal may be obtained by use of two “o-rings” 564 and 566 (which may be in a shape like that or other than that of the letter “o,” such as a rounded rectangle as shown, for example) that extend around opening 532 in the top of the compartment body 530, for example. In such a case, the two “o-rings” may be separated by a cavity 568 and may be sufficient to form dual seal 570, as shown. A vacuum pump (not shown) may be associated with cavity 568, such that a high quality seal is provided, for example. A pressure sensor (not shown) may be associated with the cavity, such that any seal failure may be detected or indicated, for example. A failure of the “o-ring” seal on the atmospheric side may be indicated by a rise in pressure, for example, and a failure of the “o-ring” on the vacuum side may be indicated by a drop in pressure, for example. When any such failure is indicated, the “o-ring” associated with the failure may be replaced at an appropriate time, such as the next time compartment body 534 is vented, for example.

At least one module, such as a pump module or a sputtering module, for example, may be moved from one compartment to another in a coating system, as now described in relation to FIG. 6. For example, a sputtering module 612 may be moved from a compartment Y to a compartment Z, as schematically illustrated in FIGS. 6A and 6B. In preparation for such movement, a process module that comprises multiple compartments, such as compartments Y and Z, or compartments X, Y and Z, as illustrated, for example, may be vented to atmosphere. For example, a single process module comprising isolation slit valves (not shown) at each end thereof, may be vented by closing the isolation slit valves, turning off pumps associated with the process module, and introducing gas (such as air or inert gas, for example) into the process module. Further by way of example, several process modules may be so vented at one time by closing isolation slit valves located at various locations throughout the coating system, turning off pumps associated with the process modules, and introducing gas into the process modules. A suitable slit valve or slit valve chamber, such as any of those shown in U.S. patent application Ser. No. 11/150,360, entitled “Dual Gate Isolating Maintenance Slit Valve Chamber with Pumping Option,” which is hereby incorporated by reference in its entirety, for example, any of those shown and described in relation to FIGS. 5-9 of that application, may be employed in appropriate locations, such as between adjacent process modules, for example. Appropriate connections (if any), such as manual connections, for example, may be disconnected and movement may be initiated.

Any suitable means or methods of movement may be employed. For example, a hoist may be attached to sputtering module 612 via attachment points on the sputtering module and employed to lift the sputtering module sufficiently relative to the body of compartment Y, such that any appropriate automatic connections, such as electrical supply connections, interlock connections, cooling water connections, and/or any other appropriate automatic connections associated with the sputtering module, for example, are disconnected, as will be appreciated in relation to the discussion concerning such movement and such connections associated with FIG. 5. Sputtering module 612 may then be moved toward another compartment, such as laterally to an appropriate position over compartment Z, as shown in FIG. 6A, for example, whereupon it may be lowered relative to compartment Z, as shown in FIG. 6B, for example. When sputtering module 612 is sufficiently positioned and lowered relative to compartment Z, appropriate automatic connections, such as electrical supply and cooling water supply connections, for example, are made, as will be appreciated in relation to the discussion concerning such movement and such connections associated with FIG. 5.

It will be understood that the automatic electrical supply connection just described does not require movement of cables. For example, any of the compartments of a process module, such as compartments Y and Z, or compartments X, Y and Z, for example, may be supplied with appropriate, compatible, or identical electrical supply and cooling water supply connections. In such a case, when sputtering module 612 is moved from compartment Y to compartment Z, it may be automatically connected to the electrical supply associated with compartment Z, as will be appreciated in relation to the discussion concerning such movement and such connection associated with FIG. 5. In such a case, it is not necessary to relocate an electrical supply cable from one compartment to another. Other or manual connections (if any) may also be made, as will be appreciated in relation to the discussion concerning such control and secondary electrical supply connections associated with FIG. 5, for example. Once appropriate automatic connections, such as electrical supply and cooling water connections, for example, are made, and any appropriate other or manual connections (if any), are made, compartment Z may be prepared for a sputtering operation, such as via pumping, for example, without requiring additional reconfiguration. In such a case, it is not necessary to provide mapping information to the controller.

As described above, at least one module, such as a pump module or a sputtering module, for example, may be moved from one compartment to another in a coating system, as now described in relation to FIG. 6. For example, a pump module 610 may be moved from a compartment X to a compartment Y, as schematically illustrated in FIGS. 6A and 6B. Pump module 610 has a lid 614 sufficient to fit or to cover a compartment opening 600, such as a standard size compartment opening, for example. Pump module 610 may comprise at least one pump, such as the three vacuum pumps 618, 620, and 622 shown in FIG. 6C, for example, which are associated with or attached to lid 614, and which may be at least partially covered or enclosed by housing or cover 616. Any suitable pump, such as a turbomolecular pump (turbo pump), for example, may be used. Pump module 610 may be moved from compartment X to compartment Y in any appropriate manner, such as via any of the hoist, position, and lower movements described above in relation to the movement of sputtering module 612, for example. In preparation for such movement, a process module that comprises compartments X and Y, or compartments X, Y and Z, as illustrated, for example, may be vented to atmospheric pressure. Any appropriate connection associated with pump module 610, such as any manual connection, for example, may be disconnected.

By way of example, a connection of pump module 610 to foreline 624 is disconnected in preparation for movement of pump module 610 from one compartment to another. Foreline 624 is generally a vacuum conduit that links at least one pump, such as the three vacuum pumps 618, 620, and 622 shown in FIG. 6C, for example, to a backing pump (not shown). Foreline 624 may be a common foreline that is shared by multiple pump modules, although multiple forelines may be employed, as desired. Foreline 624 may be common to all pump modules associated with a processing module or to all pump modules in a coating system, although multiple forelines may be employed, as desired. At least one such foreline 624 is generally sufficient to maintain an appropriate level of vacuum associated with an exhaust side of at least one turbo pump, such that the turbo pump may operate efficiently and such that a vacuum level of up to a few millitorrs, such as about 1 millitorr to about 9 millitorrs, for example, may be associated with a process module. Foreline 624 may be automatically disconnected from pump module 610, such as via a foreline branch 626 described below, as the pump module is lifted sufficiently relative to the body of compartment X.

Foreline 624 may be equipped with at least one connector, such as the three connectors 628x, 628y, and 628z, for example, that is associated with at least one compartment, such as the three compartments X, Y and Z, respectively, for example, as illustrated in FIG. 6A and FIG. 6B. If any connector, such as 628y and 628z of FIGS. 6A and 628x and 628z of FIG. 6B, is not to be used, for example, when it is associated with a compartment that is other than a pump compartment, it may be in a closed, inaccessible, or blanked-off state. If any connector, such as 628x of FIGS. 6A and 628y of FIG. 6B, is to be used, for example, when it is associated with a pump compartment, it may be in an open or accessible state. If compartment Y to which pump module 610 is being moved is not initially configured as a pump compartment, as illustrated in FIG. 6A, compartment Y may be provided with a foreline branch 626, as illustrated in FIG. 6B and FIG. 6C, that facilitates connection of pump module 610 and connector 628y, and thus foreline 624. Foreline branch 626 may extend to more or less the top of compartment Y, as illustrated in FIG. 6B and FIG. 6C, and may comprise or be associated with a bellows 630. It will be understood that, alternatively or additionally, a bellows (not shown) may be associated with a lower portion of pump line 636. Bellows 630 may comprise or be associated with a flange 632 sufficient for operable communication with a corresponding flange 634 associated with pump module 610. Flange 632 and corresponding flange 634 may be clamped together or otherwise associated to provide sufficient connection. For example, clamping may not be necessary, such that pump module 610 may be positioned and lowered sufficiently such that flange 634 and flange 632 meet, align, and/or interact sufficiently to operably associate pump module 610 with foreline branch 626. Alignment features (such as alignment pins and/or sockets, for example) associated with pump module 610 may facilitate centering or alignment of flange 632 relative to flange 634 as sputtering module 610 is lowered. When pump module 610 is lowered sufficiently, bellows 630 may be compressed. Bellows 630 may provide flange 632 with some freedom of movement to facilitate alignment with flange 634. In such a manner, or any other appropriate manner, foreline 624 and pump module 610 may be automatically connected and disconnected as the pump module is moved.

Another view of pump module 610 and compartment Y of FIG. 6B is illustrated in FIG. 6C. In this illustration, foreline 624, foreline branch 626 and bellows 630 are shown in relation to one side of compartment Y. As shown, flange 632 is operably associated with flange 634 of pump module 610. Flanges 632 and 634 may be so associated via spring action of bellows 630, which may be compressed via pump module 610, for example. As mentioned previously, a bellows may also or alternatively be associated with a vacuum line 636, such as near flange 634, for example. Flanges 632 and 634 may be operably associated with one another via atmospheric pressure, such as upon appropriate pumping of compartment Y. At least one vacuum line 636 may be used to operably associate at least one pump, such as at least one of pumps 618, 620 and 622, and foreline branch 626, and thus foreline 624.

In general, a pump module, such as pump module 610, may be operated using less power, such as about up to 6 kW per module or up to about 1 kW per pump per module, for example, than that generally associated with a sputtering module, such as sputtering module 612, which may be relatively high. The pump module 610 may be provided with sufficient power by a secondary electrical supply, for example, which may be manually connected to the pump module. The pumps associated with the pump module may be cooled via a relatively small amount of cooling fluid or water, such as about 3 gpm, for example. The cooling fluid or water may be provided via relatively small cooling water lines, which may be manually connected to the pump module. Electrical power, cooling and/or control connections may be manual connections, or may be automatic connections, as may be facilitated by automatic connectors, such as those previously described. A compartment may have connections, such as standard connections, for example, which may be used in association with a module, whether the module is a pump module or a sputtering module. When the module is a pump module, a foreline connection is also provided, as previously described. For example, a foreline branch may occupy space on a side of the compartment that might otherwise be occupied by an automatic connector associated with the compartment. In such a case, when a pump module is to be associated with a compartment, an automatic connector associated with the compartment may be removed, a foreline branch may be provided, as previously described, and electrical, control and cooling water connections may be made manually. A compartment may be associated with a foreline branch and automatic electrical power and water connections, such that the compartment may be configured for pumping or sputtering. In such a case, simply placing a module appropriately relative to the compartment may be sufficient for configuring the compartment for use as either a pump compartment or a sputtering module.

When a compartment, such as compartment X of FIG. 6B, is not to be used, its opening may be blanked off or closed, via a lid 638, for example. A seal may be formed between lid 638 and the body of compartment X, in a manner such as that associated with creating a seal between a lid of a pumping module or a sputtering module and a body of a compartment, such that compartment X is vacuum-tight. Coaters may be configured with compartments that are not used, for a variety of reasons. For example, a coater may be so configured in order to have a capacity that may be desired at a later time, such as upon expansion of a coating application, for example. An unused compartment in a modular coating system may be configured for pumping or sputtering relatively easily and quickly, as will be appreciated from the description herein.

A gas isolation tunnel 640 is associated with compartment X of FIG. 6A and a gas isolation tunnel 641 is associated with compartment Y of FIG. 6B. Tunnels 640 and 641 are formed by baffling that partially surrounds the pathway by which a substrate passes through a compartment and reduces gas flow associated with that pathway. This reduction in gas flow is generally desirable, as it reduces or prevents migration of a gas from one compartment to another, or inter-compartmental cross-contamination. Pump slots 644 associated with compartment Y of FIG. 6A are located near pump module 610 and near the top of the compartment. Pump slots 644 associated with compartment X of FIG. 6B are located near pump module 610 and near the top of the compartment. Pumps of pump module 610 remove gas from compartments of a process module via these pump slots 644. As shown in FIGS. 6A and 6B, pump slots are associated with all of the compartments of the process module, such that vacuum in the process module may be maintained by the pumps.

A central controller may be used to control sputtering modules and other components of a coating system. A central controller may be a programmable logic controller (PLC), a personal computer (PC), a mainframe computer, or some other system sufficient to execute control software. Each compartment may be associated with a dedicated control connection that is not moved when the compartment is moved. When a module, be it a pump module or a sputtering module, is moved to a new compartment, it is connected to the control connection for that new compartment. The module may be associated with a unique identifier, such that via a signal from the new compartment to the controller, the controller recognizes that the uniquely identified module is connected to the new compartment. In a similar manner, the controller may recognize or record a property or several properties of the uniquely identified module. For example, the controller may recognize the module as an AC sputtering module or as a DC sputtering module. If nothing is connected to the control connection associated with a compartment, the controller may assume the compartment is not to be used. Examples of systems that may be used to connect a controller to one or more sputtering module(s) and/or pump module(s) include Devicenet systems and Profibus systems. Unique identifiers may be associated with sputtering modules and other components by setting jumpers in the components.

By way of example, in the situation shown in FIG. 6B, the control connector associated with compartment X would not be connected to anything, such that the controller would recognize compartment X as a compartment that is not to be used; the control connector associated with compartment Y would be connected to pump module 610, such that the controller would recognize that pump module is associated with compartment Y; and the control connection associated with compartment Z would be connected to sputtering module 612, such that the controller would recognize that sputtering module 612 is associated with compartment Z. As such, a user need not enter mapping data into the controller, such as via manual entry, for example. As such, failure or mistake that may be associated with such user entry of mapping data into the controller, may be avoided. When the controller recognizes a particular module, such as a pump module or a sputtering module, for example, it is capable of executing control software or a control algorithm appropriate for that module.

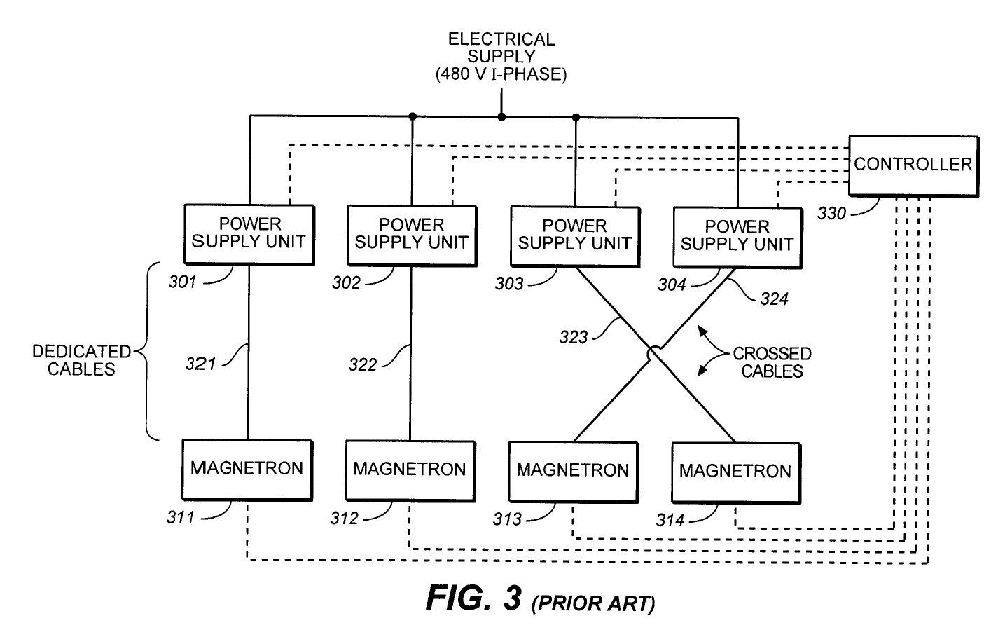

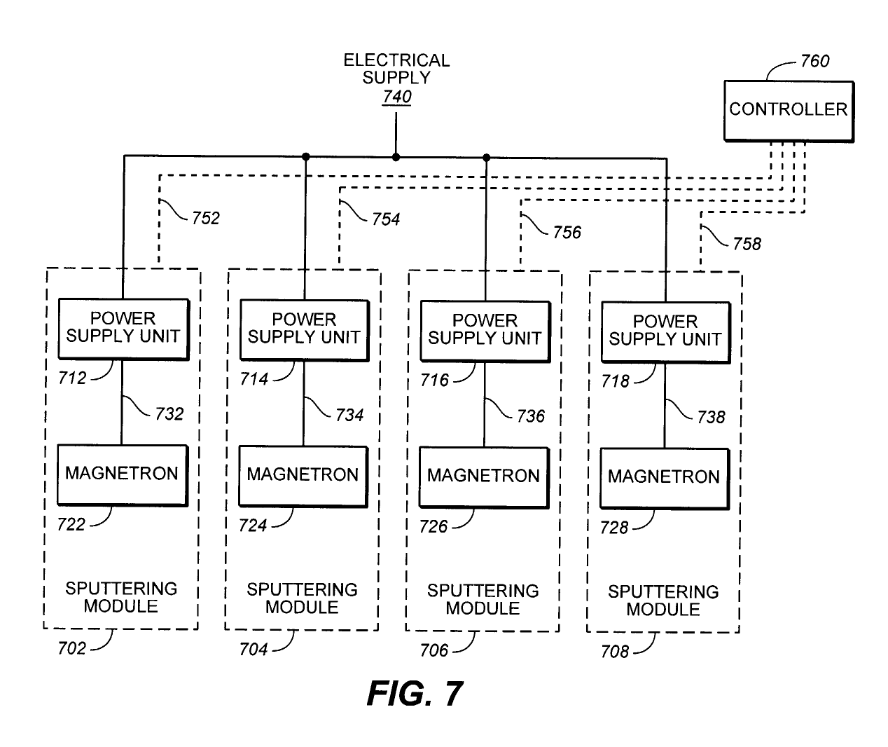

A modular sputtering system comprising four compartments is now described in relation to the block diagram of FIG. 7. Each of the four compartments of the system is associated with a sputtering module, such that four sputtering modules 702, 704, 706 and 708 are shown. Each of the sputtering modules comprises a power supply unit and a magnetron that are electrically connected to one another by a cable. As such, four power supply units 712, 714, 716 and 718, four magnetrons 722, 724, 726 and 728, and four cables 732, 734, 736 and 738 are shown. The cables may be short and may be at least partially enclosed by housings or covers, such as covers that may reduce or eliminate RF interference outside the covers, for example. Each set of a power supply unit, a magnetron and a cable, such as power supply unit 712, magnetron 722, and cable 732, for example, may be provided in a single physical unit, such as sputtering module 702, for example. Such a configuration may be advantageous in that it may serve to eliminate erroneous connection of one or more power supply unit(s) and magnetron(s) of the system, such as that described previously in relation to FIG. 3. The four sputtering modules 702, 704, 706 and 708 may share a common electrical supply 740, as shown, such that no special cabling extending beyond the sputtering modules is needed. Each of the four communication cables 752, 754, 756 and 758 may be dedicated to a particular compartment and may provide controller 760 with information regarding the sputtering module (or other module) that is associated with that compartment.

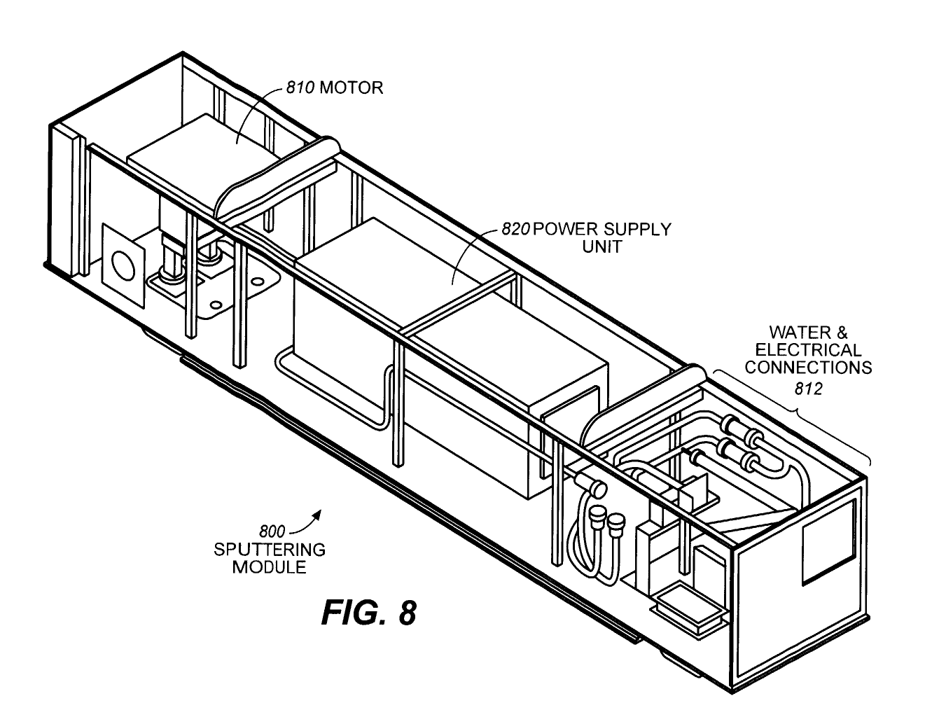

A sputtering module is now described in relation to FIG. 8. The sputtering module 800 is shown with its housing or cover partially removed. A motor 810 for providing rotational force to a drive endblock and a target (not visible in FIG. 8) may be located at one end of sputtering module 800, as shown. Water and electrical connections 812 for providing water and electricity to a water endblock may be located at the other end of sputtering module 800, as shown. Additionally, a power supply unit 820 for providing power to the water endblock may be located in a middle portion of the sputtering module 800, as shown. Power supply unit 820 may be supplied with cooling fluid or water sufficient for cooling the power supply unit. The cooling of the power supply unit may be important given that the power supply is enclosed and in proximity to other high power equipment.

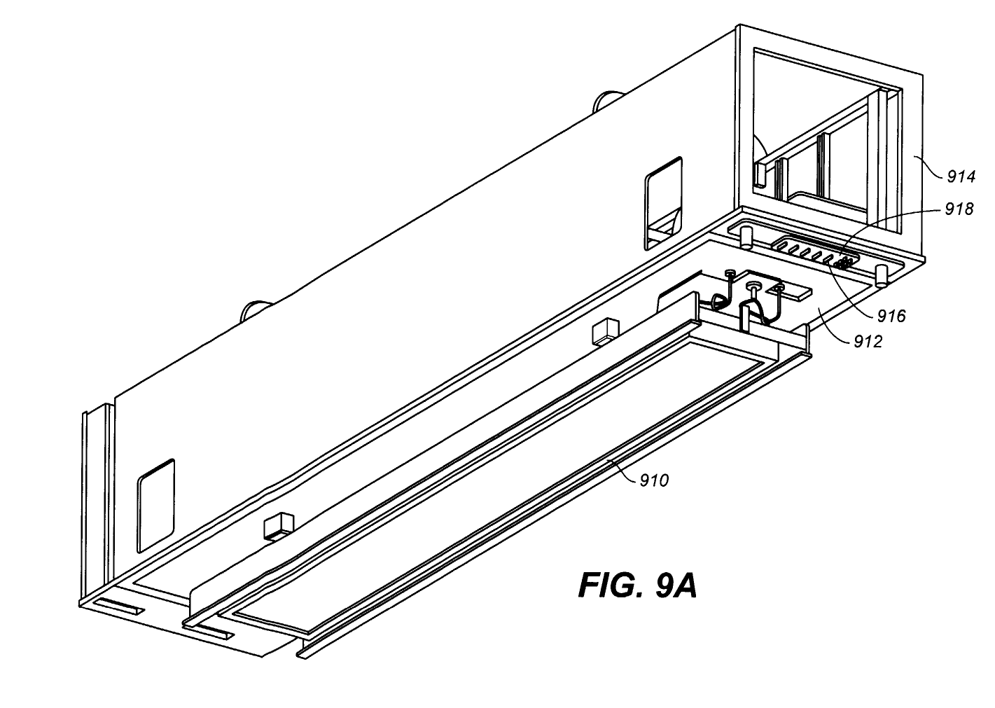

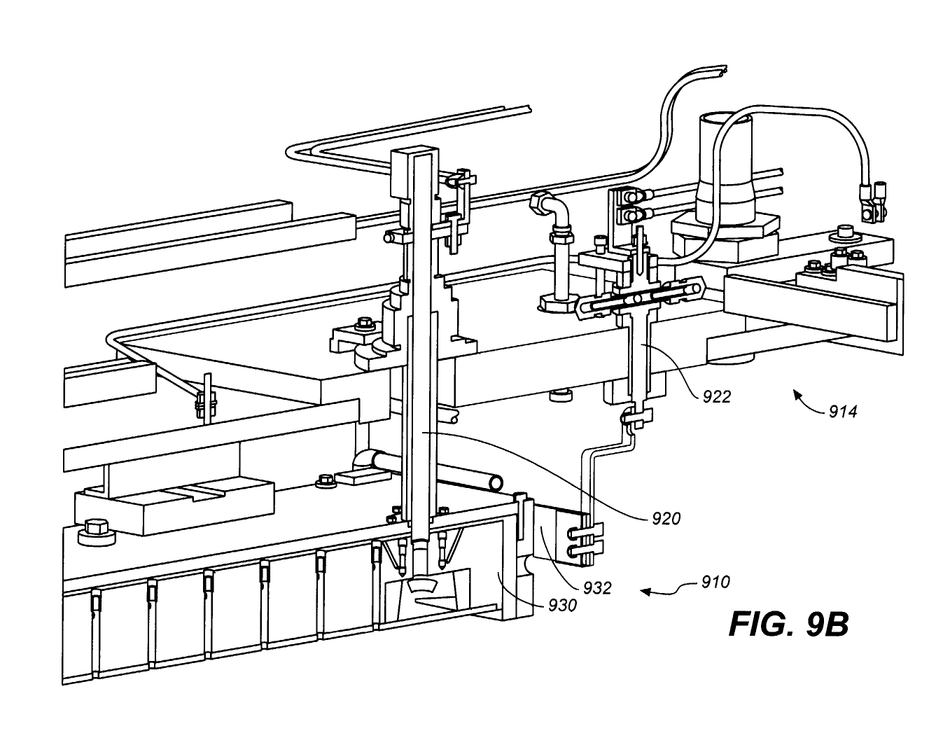

It will be understood that a sputtering system may comprise at least one planar magnetron. In such a case, a planar magnetron 910 may be physically associated with or attached to a lid 912 of a module 914 or another lid of another module associated with a nearby or an adjacent compartment (not shown) or located somewhere on the coater by any appropriate means or devices, as schematically illustrated in FIG. 9A. An automatic connector 918 may comprise connector elements 916 (collectively), be they in pin, blade, and/or other appropriate form, which are appropriate for connection with corresponding connector elements (not shown) that are associated with a compartment (not shown), such as in the manner previously described in relation to FIG. 5, for example. When a planar magnetron is used, endblocks are not required, such that the endblock connections mentioned in relation to the sputtering module of FIG. 5 and FIG. 8 are not required. As schematically illustrated in FIG. 9B, a power or an electrical connection to a cathode 930 of the planar magnetron 910 may be made via a power feed-through 920 and a power or an electrical connection to an anode 932 of the planar magnetron 910 may be made via another power feed-through 922. The power or electrical connection to the cathode 930 and the anode 932 may be via a connection to a negative and a positive output, respectively, of a power supply unit (not shown), such as power supply unit associated with the module 914, for example.

Various modifications, processes, as well as numerous structures that may be applicable herein will be apparent. Various aspects, features or embodiments may have been explained or described in relation to understandings, beliefs, theories, underlying assumptions, and/or working or prophetic examples, although it will be understood that any particular understanding, belief, theory, underlying assumption, and/or working or prophetic example is not limiting. Although the various aspects and features may have been described with respect to various embodiments and specific examples herein, it will be understood that any of same is not limiting with respect to the full scope of the appended claims or other claims that may be associated with this application.

1. A module for use in association with a coater that comprises at least one compartment, the module comprising:
a lid sufficient to fit an opening of the compartment; and
a power supply physically associated with the lid, another lid associated with a nearby compartment, or the coater, the power supply sufficient to receive an electrical input and to provide an electrical output sufficient for sputtering within the compartment.

2. The module of claim 1, wherein the power supply is sufficient to maintain or to modify the electrical output based on a predetermined point or a predetermined range.

3. The module of claim 1, wherein the electrical input is a three-phase alternating current input from about 380 volts to about 600 volts a 380-volts and about 50 Hertz to about 60 Hertz.

4. The module of claim 1, further comprising a magnetron physically associated with the lid.

5. The module of claim 4, wherein the magnetron is selected from a planar magnetron and a cylindrical magnetron.

6. The module of claim 4, wherein the magnetron is a cylindrical magnetron and the module further comprises a first endblock and a second endblock physically associated with the lid, the first endblock and the second endblock together sufficient for supporting the cylindrical magnetron.

7. The module of claim 1, further comprising a cover that at least partially encloses the power supply.

8. The module of claim 1, further comprising a cover, wherein the power supply is physically associated with the lid via the cover.

9. A module for use in association with a coater that comprises at least one compartment and at least one compartment connector associated with the compartment, the module comprising:
a module comprising a lid sufficient to fit an opening of the compartment;
a power supply physically associated with the lid, or another lid associated with a nearby compartment, or the coater, the power supply sufficient to receive an electrical input and to provide an electrical output sufficient for sputtering within the compartment; and
a connector physically associated with the module sufficient for connecting with the compartment connector when the lid and the compartment are sufficiently positioned relative to one another, such that electrical communication is provided between the power supply and the compartment.

10. A module for use in association with a coater that comprises at least one compartment and at least one compartment connector associated with the compartment, the module comprising:
a module comprising a lid sufficient to fit an opening of the compartment;
a power supply physically associated with the lid, another lid associated with a nearby compartment, or the coater, the power supply sufficient to receive an electrical input and to provide an electrical output sufficient for sputtering within the compartment; and
a connector physically associated with the module sufficient for connecting with the compartment connector when the lid and the compartment are sufficiently positioned relative to one another, such that fluid communication is provided between a fluid supply and the compartment.

11. A module for use in association with a coater that comprises at least one compartment and at least one control connector associated with the compartment, the module comprising:
a module comprising a lid sufficient to fit an opening of the compartment; and
a power supply physically associated with the lid, another lid associated with a nearby compartment, or the coater, the power supply sufficient to receive an electrical input and to provide an electrical output sufficient for sputtering within the compartment;
wherein the module is sufficient for connection with the control connector, such that controlled electrical communication is provided between the power supply and the compartment.

12. A module for use in association with a coater that comprises at least one compartment and at least one control connector associated with the compartment and sufficient for communication with a controller, the module comprising:
a module comprising a lid sufficient to fit an opening of the compartment; and
a power supply physically associated with the lid, another lid associated with a nearby compartment, or the coater, the power supply sufficient to receive an electrical input and to provide an electrical output sufficient for sputtering within the compartment;
wherein the module is sufficient for connection with the control connector and is associated with an identifier sufficient for recognition by the controller.

13. A module for use in association with a coater that comprises at least one compartment, at least one foreline, and at least one foreline connector physically associated with the foreline, the module comprising:
a lid sufficient to fit an opening of the compartment;
at least one pump physically associated with the lid and sufficient to provide vacuum to the compartment; and
a module connector physically associated with the module and sufficient for automatically connecting with the foreline connector when the lid and the compartment are sufficiently positioned relative to one another.

14. The module of claim 13, wherein at least one connector of the foreline connector and the module connector comprises a bellows.
